(19) United States
(12) Patent Application Publication
(10) Pub. No.: US 2026/0081571 A1
(43) Pub. Date: Mar. 19, 2026

(54) NEUTRAL POINT CLAMPED MULTILEVEL SWITCHING AUDIO AMPLIFIER

(71) Applicant: TEXAS INSTRUMENTS INCORPORATED, Dallas, TX (US)

(72) Inventors: Saad Pervaiz, Tyler, TX (US); Pourya Assem, Dallas, TX (US); David Baldwin, Allen, TX (US); Timothy Merkin, Princeton, TX (US)

(21) Appl. No.: 18/886,919

(22) Filed: Sep. 16, 2024

(51) Int. Cl. H03F 3/217; H03F 1/02

(52) U.S. Cl. CPC H03F 3/217; H03F 1/0205; H03F 2200/03

(57) ABSTRACT

An apparatus may include a set of terminals, a first switch circuit, and a second switch circuit. The set of terminals can include a power supply terminal, a reference terminal, and an intermediate voltage terminal. The first switch circuit, which can include a first set of control inputs and a positive drive terminal, is configured to, responsive to a first set of control signals applied to the first set of control inputs, selectively couple a first terminal of the set of terminals to the positive drive terminal. The second switch circuit, which can include a second set of control inputs and a negative drive terminal, is configured to, responsive to a second set of control signals applied to the second set of control inputs, selectively couple either the first terminal or a second terminal of the set of terminals to the negative drive terminal.

### BACKGROUND

A switching amplifier, such as a class-D amplifier, includes transistors that operate as switches to amplify a low voltage and low power audio input signal to a higher voltage and higher power audio signal that can be used to drive a speaker. This switching amplifier operation provides various benefits, particularly in comparison with linear amplifiers. For example, compared with linear amplifiers, switching amplifiers may have much lower power dissipation and thus higher efficiency because the switching transistors in switching amplifiers may be either fully turned on or fully turned off (rather than in the linear operating condition), which are some among various factors that make switching amplifiers attractive for audio applications.

### SUMMARY

This Summary is provided to introduce examples of disclosed concepts in a simplified form, which are further described below in the Detailed Description including the drawings provided.

According to certain aspects, an apparatus may include a set of terminals including a power supply terminal, a reference terminal, and an intermediate voltage terminal; a first switch circuit coupled to the set of terminals and including a first set of control inputs and a positive drive terminal, wherein the first switch circuit is configured to, responsive to a first set of control signals applied to the first set of control inputs, selectively couple a first terminal of the set of terminals to the positive drive terminal; and a second switch circuit coupled to the set of input terminals and including a second set of control inputs and a negative drive terminal, wherein the second switch circuit is configured to, responsive to a second set of control signals applied to the second set of control inputs, selectively couple one of the first terminal or a second terminal of the set of terminals to the negative drive terminal.

According to certain aspects, an apparatus can include a first switch circuit and a second switch circuit. The first switch circuit may include a first switch coupled between a power supply terminal and a positive drive terminal; a second switch coupled between a reference terminal and the positive drive terminal; and a third switch coupled between an intermediate voltage terminal and the positive drive terminal, wherein the third switch includes a bidirectional switch. The second switch circuit may include a fourth switch coupled between the power supply terminal and a negative drive terminal; a fifth switch coupled between the reference terminal and the negative drive terminal; and a sixth switch coupled between the intermediate voltage terminal and the negative drive terminal.

According to certain aspects, a method can include, in a first interval connecting a first speaker terminal to a power supply terminal; connecting a second speaker terminal to an intermediate voltage terminal; and disconnecting the second speaker terminal from a reference terminal; and in a second interval, connecting the first speaker terminal to the intermediate voltage terminal; and connecting the second speaker terminal to the reference terminal.

The foregoing summary outlines rather broadly various features of examples of the present disclosure so that the following detailed description may be better understood. Additional features and advantages of such examples will be described hereinafter. This summary is neither intended to identify key or essential features of the claimed subject matters, nor is it intended to be used in isolation to determine the scope of the claimed subject matters. The subject matters should be understood by reference to appropriate portions of the entire specification of this disclosure, any or all drawings, and each claim. The foregoing, together with other features and examples, will be described in more detail below in the following specification, claims, and accompanying drawings.

### BRIEF DESCRIPTION OF THE DRAWINGS

Illustrative examples are described in detail below with reference to the following figures.

FIG. 1 is a schematic of an example of a switching amplifier that can be included in an apparatus.

FIG. 2 is a schematic illustrating some example components that may be included in a switching amplifier.

FIG. 3 is a schematic of a first example of the switching amplifier shown in FIG. 1.

FIG. 4A shows a set of waveforms that may be present in response to a first switching cycle of control signals applied to the switching amplifier shown in FIG. 3.

FIG. 4B shows a set of waveforms that may be present in response to a second switching cycle of control signals applied to the switching amplifier shown in FIG. 3.

FIG. 5 shows another set of waveforms that may be present in response to a first switching cycle of control signals applied to the switching amplifier shown in FIG. 3.

FIGS. 6A, 6B, and 6C show waveforms that may be observed at various terminals during operation of the switching amplifier shown in FIG. 3.

FIG. 7 is a schematic of a second example of the switching amplifier shown in FIG. 1.

FIG. 8A shows a set of waveforms that may be present in response to a first switching cycle of control signals applied to the switching amplifier shown in FIG. 7.

FIG. 8B shows another set of waveforms that may be present in response to a second switching cycle of control signals applied to the switching amplifier shown in FIG. 7.

FIG. 9 shows a set of waveforms corresponding to various signals that may be observed in the switching amplifier shown in FIG. 7.

FIG. 10 is a schematic of a third example of the switching amplifier shown in FIG. 1.

FIG. 11 shows a set of waveforms corresponding to various signals that may be observed in the switching amplifier shown in FIG. 10.

FIG. 12 shows a first example of a pulse width modulator circuit that can be included in switching amplifier shown in FIG. 1.

FIG. 13 shows a second example of a pulse width modulator circuit that can be included in switching amplifier shown in FIG. 1.

FIG. 14 shows a set of waveforms corresponding to control signals that may be observed when the pulse width modulator circuit shown in FIG. 13 is included in the switching amplifier shown in FIG. 10.

FIG. 15 shows a set of waveforms corresponding to various signals that may be observed in the switching amplifier shown in FIG. 10.

FIG. 16 shows a flowchart of operations that may be associated with the switching amplifier shown in FIG. 1.

The drawings and accompanying detailed description are provided for understanding of features of various examples and do not limit the scope of the appended claims. The examples illustrated in the drawings and described in the accompanying detailed description may be readily utilized as a basis for modifying or designing other examples that are within the scope of the appended claims. One skilled in the art will readily recognize from the following description that alternative embodiments of the structures and methods illustrated may be employed without departing from the principles, or benefits touted, of this disclosure. Identical reference numerals may be used, where possible, to designate identical elements that are common among drawings. The figures are drawn to clearly illustrate the relevant elements or features and are not necessarily drawn to scale.

### DETAILED DESCRIPTION

The present disclosure relates generally to neutral point clamped multilevel switching audio amplifiers. In some examples described herein, an amplifier includes a symmetric power stage and a shared neutral point terminal, which provides an intermediate voltage between a first voltage (e.g., a power supply voltage) and a second voltage (e.g., a ground voltage). The neutral point terminal can be coupled to a pair of capacitors. The amplifier can include multiple switching circuits, which in response to control signals, operate and balance the pair of capacitors to clamp the neutral point terminal at the intermediate voltage.

An example apparatus can include a set of terminals including a power supply terminal, a reference terminal, and an intermediate voltage terminal. The example apparatus can further include a first switch circuit coupled to the set of terminals. The first switch circuit can include a first set of control inputs and a positive drive terminal. The first switch circuit is configured to, responsive to a first set of control signals applied to the first set of control inputs, selectively couple a first terminal among the set of input terminals to the positive drive terminal. The example apparatus can further include a second switch circuit coupled to the set of terminals. The second switch circuit can include a second set of control inputs and a negative drive terminal. The second switch circuit is configured to, responsive to a second set of control signals applied to the second set of control inputs, selectively couple either the first terminal or a second terminal of the set of terminals to the negative drive terminal.

The first switch circuit and the second switch circuit can be a part of a symmetric power stage of a switching amplifier. More particularly, the symmetric power stage includes the first switch circuit coupled via a first low pass filter to a first terminal of a speaker. The symmetric power stage also includes the second switch circuit coupled via a second low pass filter to a second terminal of the speaker in a symmetric arrangement with respect to the speaker. A first amplitude of a positive current flow through the speaker from the first terminal to the second terminal in response to a first switching cycle of a control signal is substantially the same as a second amplitude of a negative current flow through the speaker from the second terminal to the first terminal in response to a second switching cycle of the control signal. The balanced current flow through the speaker during the two control cycles enables the pair of capacitors to clamp the neutral point voltage at the intermediate voltage over multiple switching cycles of the control signal.

The apparatus can also include a control circuit having an input, a first set of control signal outputs, and a second set of control signal outputs. The first set of control signal outputs of the control circuit are coupled to the first set of control inputs of the first switch circuit and the second set of control signal outputs of the control circuit are coupled to the second set of control inputs of the second switch circuit. The control circuit is configured to provide the first set of control signals to the first set of control inputs and the second set of control signals to the second set of control inputs in response to a signal provided at the input of the control circuit. The control signals selectively place each transistor of the first switch circuit and the second switch circuit, in either an on state or an off state, for selectively coupling the first terminal of the set of input terminals to the positive drive terminal and the second terminal of the set of input terminals to the negative drive terminal. The first terminal and the second terminal can be either a power supply terminal, a reference terminal, or an intermediate voltage terminal.

The intermediate voltage terminal is located at a junction of the pair of capacitors that provide neutral point clamping at the intermediate voltage. The pair of capacitors includes a first capacitor coupled between the power supply terminal and the intermediate voltage terminal, and a second capacitor coupled between the intermediate voltage terminal and the reference terminal.

The pair of capacitors can be provided external to a device (such as an integrated circuit, for example) and connected to the device via a single pin of the device. The single pin of the device is connected inside the device to both the first switch circuit and the second switch circuit, thereby providing a shared junction at which neutral point clamping occurs. This arrangement eliminates the need to provide a first pair of capacitors coupled to the first switch circuit and a second pair of capacitors coupled to the second switch circuit. Using two pairs of capacitors not only increases the pin count to two (one for each pair), but may also lead to distortion in sound produced by the speaker if a mismatch exists between the first pair of capacitors and the second pair of capacitors. The mismatch can be due to various factors such as, for example, differences in capacitance values, differences in capacitance tolerances, and changes in capacitance values over temperature, humidity, etc.

Even when using a single pair of capacitors, a characteristic of a first capacitor may not match a characteristic of a second capacitor of the pair of capacitors. For example, a performance parameter, or capacitance value, of the first capacitor over a range of operating temperatures may be different than a performance parameter, or capacitance value, of the second capacitor over the range of operating temperatures. Such differences between the first capacitor and the second capacitor, which may cause inconsistencies in performance of the example apparatus, can be addressed by incorporating additional circuitry into the apparatus. An example of a circuit to do so is a feedback control circuit which compares a duty cycle of a control signal output of the control circuit to a reference duty cycle and modifies the duty cycle of the control signal output upon detecting a change between the duty cycle of the control signal output of the control circuit and the reference duty cycle. The reference duty cycle may be generated by a circuit that includes a comparator that compares the intermediate voltage present at the intermediate voltage terminal against a reference voltage, such as, for example, a mid-level voltage between the power supply voltage and ground.

Modification of the duty cycle of the control signal output that is referred to above, may be carried out by use of a modulator such as, for example, a pulse width modulator. The pulse width modulator varies a pulse width of the control signal output in response to the difference between the duty cycle of the control signal output and the reference duty cycle. Varying the pulse width results in a change in duty cycle of the control signal output.

In an alternative example, modification of the duty cycle of the control signal output may be carried out by use of a pulse density modulator. The pulse density modulator varies a pulse density of the control signal output in response to the difference between the duty cycle of the control signal output and the reference duty cycle.

In an example, the first low pass filter indicated above includes a first inductor. A first lead of the first inductor is coupled to the positive drive terminal of the first switch circuit and a second lead of first inductor is coupled to the first terminal of the speaker. The second low pass filter indicated above includes a second inductor. A first lead of the second inductor is coupled to the negative drive terminal of the second switch circuit and a second lead of second inductor is coupled to the second terminal of the speaker. In an example, one or both of the first low pass filter and the second low pass filter can include a capacitor. In an example, the capacitor(s) can be coupled to the first inductor and/or the second inductor in an arrangement that minimizes or eliminates electromagnetic interference (EMI) in one or more wires or leads that may be used to couple the first inductor of the first low pass filter to the first terminal of the speaker and the second inductor of the second low pass filter to the second terminal of the speaker.

The control signals provided by the control circuit to the apparatus described above, can cause the apparatus to output a multi-level modulated signal. The multi-level modulated signal, which can have three or more voltage levels, allows each of the first inductor and the second inductor to be selected to have a small inductance value in comparison to an inductor that may be used for filtering a linear signal or a binary modulated signal. Higher levels of modulation intrinsically include a number of high frequency components that can be filtered out by the first low pass filter and the second low pass filter referred to above, by use of the inductors having a small size and small inductance value. In contrast, a binary modulated signal includes a smaller number of high frequency components that may necessitate the use of larger value inductors for low pass filtering. Smaller value inductors provide various benefits such as, for example, smaller size, smaller footprint, and higher efficiency, in comparison to large value inductors.

Furthermore, the use of a symmetric power stage and shared input splitting capacitors in the manner described herein, which provides neutral point clamping at an intermediate voltage over multiple switching cycles of the control signal, allows for more effective low pass filtering, which in turn provides more efficient switching amplifier operation.

Various features are described hereinafter with reference to the figures. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

Various examples are described herein. Although the specific examples may illustrate various aspects of the above generally described features, examples may incorporate any combination of the above generally described features (which are described in more detail in examples below). In the following description, for the purposes of explanation, specific details are set forth in order to provide a thorough understanding of examples of the disclosure. However, it will be apparent that various examples may be practiced without these specific details. For example, devices, systems, structures, assemblies, integrated circuits, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

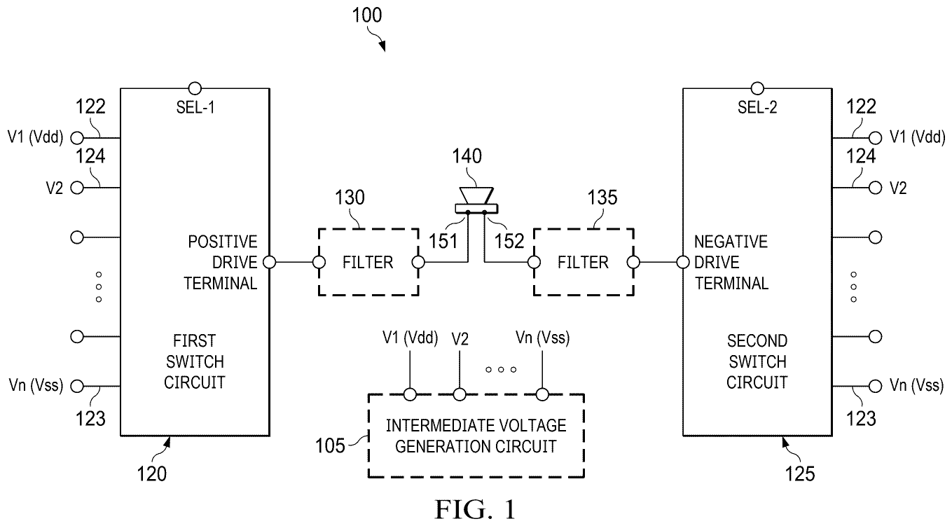

FIG. 1 is a schematic of an example switching amplifier 100 that can be included an apparatus, such as, for example, an audio system. The example switching amplifier 100 produces an amplified audio signal output via a speaker 140, in response to input audio signals. The example switching amplifier 100 includes a first switch circuit 120 and a second switch circuit 125 arranged in a symmetric configuration with respect to the speaker 140. The symmetric configuration, which can also be referred to as a mirror configuration, is composed of the first switch circuit 120 coupled via a first low pass filter 130 to a first terminal 151 of the speaker 140 and the second switch circuit 125 coupled via a second low pass filter 135 to a second terminal 152 of the speaker 140. The first terminal 151 can be, for example, a positive speaker terminal and the second terminal 152 can be, for example, a negative speaker terminal. In some examples, switching amplifier 100 can be configured/operated as a class D amplifier. In one implementation, some components (such as the first switch circuit 120 and the second switch circuit 125) may be included inside a semiconductor package and some other components such as the ones shown inside dashed line boxes can be provided external to the semiconductor package.

A set of terminals that includes a power supply terminal 122 (with voltages V1/Vdd), a reference terminal 123 (with voltages Vn/Vss), and one or more intermediate voltage terminals 124 (with a voltage V2, which can be an intermediate voltage or a neural point voltage between V1 and Vn, for example) are coupled to both first switch circuit 120 and second switch circuit 125. In this example, the various voltages provided to the set of terminals are generated by an intermediate voltage generation circuit 105 that generates one or more intermediate voltages based on a power supply voltage Vdd and a reference (Vss). Further details about the intermediate voltage generation circuit 105 are provided below.

The set of terminals (122, 123, and 124) may be coupled to the first switch circuit 120 and the second switch circuit 125. The first switch circuit 120, which includes a first set of control inputs and a positive drive terminal, is configured to selectively couple a first terminal of the set of terminals to the positive drive terminal, in response to a first set of control signals applied to the first set of control inputs. For example, the first switch circuit 120 may selectively couple a first terminal (for example, the intermediate voltage terminal) to the positive drive terminal, in response to a first set of control signals applied to the first set of control inputs. More particularly, the first set of control signals selectively place each transistor in a set of transistors (not shown) of the first switch circuit 120, in either an on state or an off state.

The first switch circuit 120 may selectively couple a second terminal (for example, Vss) to the positive drive terminal respond, in response to a second set of control signals applied to the first set of control inputs. More particularly, the second set of control signals selectively place one or more of the same transistors and/or other transistors in the set of transistors of the first switch circuit 120, in either an on state or an off state.

The set of control signals described above are varied over time in a multi-cycle format and the resultant selective coupling of either the first terminal, the second terminal, or the third terminal, to the positive drive terminal produces a multi-level modulated signal (where “n” in Vn is ≥3) at the positive drive terminal. The multi-level modulated signal is propagated to the speaker 140 via the low pass filter 130. The output of the low pass filter 130, which is selected to provide a desired low pass filtering function (cut-off frequency, ripple, etc.), is an analog signal that is coupled into the first terminal 151 of the speaker 140.

The second switch circuit 125 can include circuitry that is substantially identical to the circuitry provided in the first switch circuit 120. Further details about such circuitry is provided below. Operation of the second switch circuit 125 replicates operations described above with reference to the first switch circuit 120. The multi-level modulated signal (“n”≥3) output from the second switch circuit 125 via the negative drive terminal is propagated through the low pass filter 135. The low pass filter 130 is selected to provide a desired low pass filtering function (cut-off frequency, ripple, etc.) which can be substantially identical to the low pass filtering function provided by the low pass filter 130. The output of the low pass filter 135 is an analog signal that is coupled into the second terminal 152 of the speaker 140.

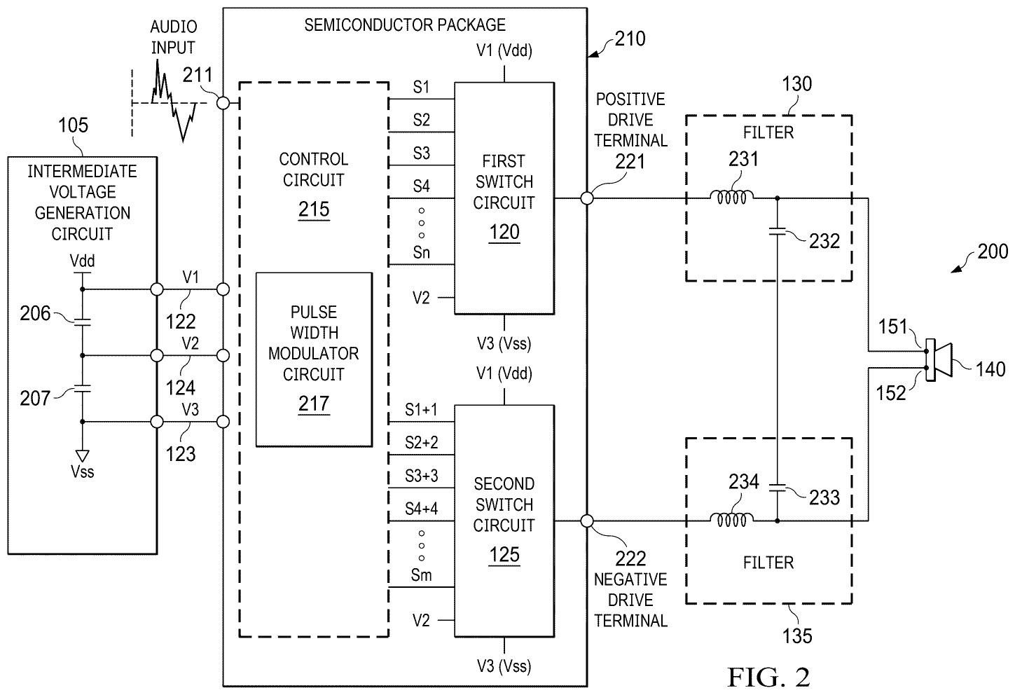

FIG. 2 is a schematic of some example components that may be included in a switching amplifier 200, which can be an example of switching amplifier 100 of FIG. 1. In this example, the first switch circuit 120 and the second switch circuit 125 are provided in a semiconductor package 210, which can be, for example, an integrated circuit. The intermediate voltage generation circuit 105 includes a first capacitor 206 and a second capacitor 207 coupled in series with the first capacitor 206. In this example, V1 is a first voltage (Vdd), V2 is an intermediate voltage, and V3 is a reference (Vss) that is coupled into the first switch circuit 120 and the second switch circuit 125 for producing the tri-level modulated output at the positive drive terminal 221 and the negative drive terminal 222.

In this example, control signals are generated by a control circuit 215 provided in the semiconductor package 210. In another example, the control circuit 215 may be provided in the form of circuitry located external to the semiconductor package 210. An audio signal can be coupled into the control circuit 215 via a terminal 211 of the semiconductor package 210 (a pin of an integrated circuit, for example). The control circuit 215 can include circuitry, such as, for example, a pulse width modulator (PWM) circuit 217, that operates upon the analog signal. More particularly, the PWM circuit 217 produces control signal outputs (S1 through Sn) that are coupled into the first switch circuit 120, and control signal outputs (Sn+1 through Sm) that are coupled into the second switch circuit 125.

As described above, the first switch circuit 120 is configured to produce a tri-level modulated signal at the positive drive terminal 221 by selectively coupling one of the first voltage (V1/Vdd), the intermediate voltage (V2), or the reference (V3/Vss), to the positive drive terminal 221, responsive to the control signals (S1 through Sn). The second switch circuit 125 is configured to produce a tri-level modulated signal at the negative drive terminal 222 by selectively coupling one of the first voltage (V1/Vdd), the intermediate voltage (V2), or the reference (V3/Vss), to the negative drive terminal 222, responsive to the control signals (Sn+1 through Sm).

In this example, the first low pass filter 130 includes an inductor 231 coupled to a capacitor 232 in a configuration that provides for low pass filtering of the tri-level modulated signal output at the positive drive terminal 221. The first low pass filter 130 is coupled between the positive drive terminal 221 and the first terminal 151 of the speaker 140.

The second low pass filter 135 includes an inductor 234 coupled to a capacitor 233 in a configuration that provides for low pass filtering of the tri-level modulated signal that is output at the negative drive terminal 222. The second low pass filter 135 is coupled between the negative drive terminal 222 and the second terminal 152 of the speaker 140.

In this example, the capacitor 232 of the first low pass filter 130 is coupled in series with the capacitor 233 of the second low pass filter 135, and the series combination of the capacitor 232 and the capacitor 233 is coupled across the speaker 140 (via the first terminal 151 and the second terminal 152). In another example either the capacitor 232 or the capacitor 233 is omitted and a single capacitor is coupled across the speaker 140 (via the first terminal 151 and the second terminal 152).

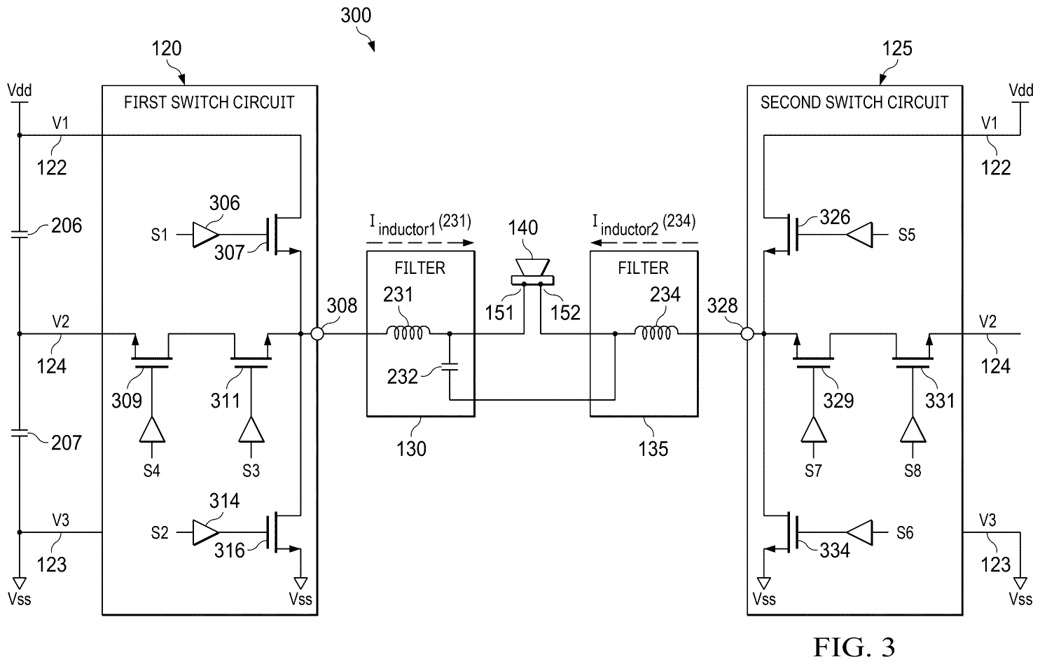

FIG. 3 is a schematic of a first example switching amplifier 300, which can be an example of switching amplifiers 100 and 200. The first switch circuit 120 and the second switch circuit 125 are configured to operate cooperatively as a symmetric power stage of the switching amplifier 300. More particularly, the symmetric power stage is composed of the first switch circuit 120 coupled via the low pass filter 130 to the first terminal 151 of the speaker 140 and the second switch circuit 125 coupled via the second low pass filter 135 to the second terminal 152 of the speaker 140, in a symmetric arrangement with respect to the speaker 140.

A first amplitude of a positive current flow through the speaker 140 from the first terminal 151 to the second terminal 152, in response to a first switching cycle of a control signal, is substantially the same as a second amplitude of a negative current flow through the speaker from the second terminal 152 to the first terminal 151 in response to a second switching cycle of the control signal. The balanced current flow through the speaker 140 during the two control cycles enables the pair of capacitors to provide neutral point clamping at an intermediate voltage, over multiple switching cycles of the control signal, possibly without additional control circuitry.

In this implementation, the first switch circuit 120 includes a first set of transistors, which in this example, is a first set of field-effect transistors (FETs), such as metal oxide semiconductor field effect transistor (MOSFET), laterally diffused metal oxide semiconductor transistor (LDMOS), high electron mobility transistor (HEMTs), etc. Other types of transistors, such as bipolar transistors (BJT), can also be used in other examples. The first set of transistors are configured to respond to a set of control signals (S1 through S4) that selectively place each transistor in the set of transistors in either an on state or an off state. The set of control inputs are varied over time in a multi-cycle format and the selective coupling of either V1 (Vdd), V2 (intermediate voltage), or V3 (Vss), by use of the multi-cycle control format, results in a tri-level modulated signal being output at the positive drive terminal 308.

More particularly, in this example, the first switch circuit 120 includes a first FET 331 coupled between the power supply terminal (Vdd) and the positive drive terminal 308; a second FET 316 coupled between the reference (Vss) and the positive drive terminal 308, and a switch pair coupled between the intermediate voltage terminal (V2) and the positive drive terminal 308.

The switch pair includes a first FET 309 coupled in series with a second FET 311 to operate as a bidirectional switch. Specifically, a drain of the first FET 309 is connected to a drain of the second FET 311. Control signals S3 and S4 can place the switch pair is any of four different states. A first of the four states involves placing both first FET 309 and second FET 311 in an off state. A second of the four states involves placing both first FET 309 and second FET 311 in an on state. A third of the four states involves placing the first FET 309 in an on state and the second FET 311 in an off state. When placed in the third state, current conduction can take place in a first direction through the first FET 309 and a body-diode (not shown) of the second FET 311, in a case where FET 311 has a body diode. A fourth of the four states involves placing the first FET 309 in an off state and the second FET 311 in an on state. When placed in the fourth state, current conduction can take place in a second direction through the second FET 311 and a body-diode (not shown) of the first FET 309, in a case where FET 309 has a body diode. For other implementations of FET 309, current can also flow via reverse conduction.

The second switch circuit 125 includes a second set of transistors, which in this example, is a second set of FETs (e.g., MOSFET, HEMT, LDMOS). Other types of transistors (e.g., BJT) can be used in other implementations. The second set of transistors are configured to respond to another set of control signals (S5 through S8) that selectively place each transistor in the set of transistors in either an on state or an off state. The set of control inputs are varied over time in a multi-cycle format and the selective coupling of either V1 (Vdd), V2 (intermediate voltage), or V3 (Vss), by use of the multi-cycle control format, results in a tri-level modulated signal being output at the negative drive terminal 328.

More particularly, in this example, the second switch circuit 125 includes a first FET 326 coupled between the power supply terminal (Vdd) and the negative drive terminal 328; a second FET 334 coupled between the reference (Vss) and the negative drive terminal 328, and a switch pair coupled between the intermediate voltage terminal (V2) and the positive drive terminal 308.

The switch pair includes a first FET 329 coupled in series with a second FET 331 to operate as a bidirectional switch. Specifically, a drain of the first FET 329 is connected to a drain of the second FET 331. Control signals S7 and S8 can place the switch pair is any of four different states. A first of the four states involves placing both first FET 329 and second FET 331 in an off state. A second of the four states involves placing both first FET 329 and second FET 331 in an on state. A third of the four states involves placing the first FET 329 in an on state and the second FET 331 in an off state. When placed in the third state, current conduction can take place in a first direction through the first FET 329 and a body-diode (not shown) of the second FET 331, in a case where FET 331 has a body diode. A fourth of the four states involves placing the first FET 329 in an off state and the second FET 331 in an on state. When placed in the fourth state, current conduction can take place in a second direction through the second FET 331 and a body-diode (not shown) of the first FET 329, in a case where FET 329 has a body diode. For other implementations of FET 329, current can also flow via reverse conduction.

An example set of waveforms corresponding to operations associated with the application of control inputs S1 through S4 to the first switch circuit 120 and S5 though S8 to the second switch circuit 125, in the multi-cycle format, is described below with reference to various figures. The tri-level modulated signal output at the positive drive terminal 308 may allow for a reduction in size of the inductor 231 in the low pass filter 130. The reduction in size is in comparison to a size of an inductor that is a part of a low pass filter used for filtering a two-level (binary) modulated signal. The tri-level modulated signal output at the negative drive terminal 328 may allow for a reduction in size of the inductor 234 in the low pass filter 135. Again, the reduction in size is in comparison to a size of an inductor that is a part of a low pass filter used for filtering a two-level (binary) modulated signal.

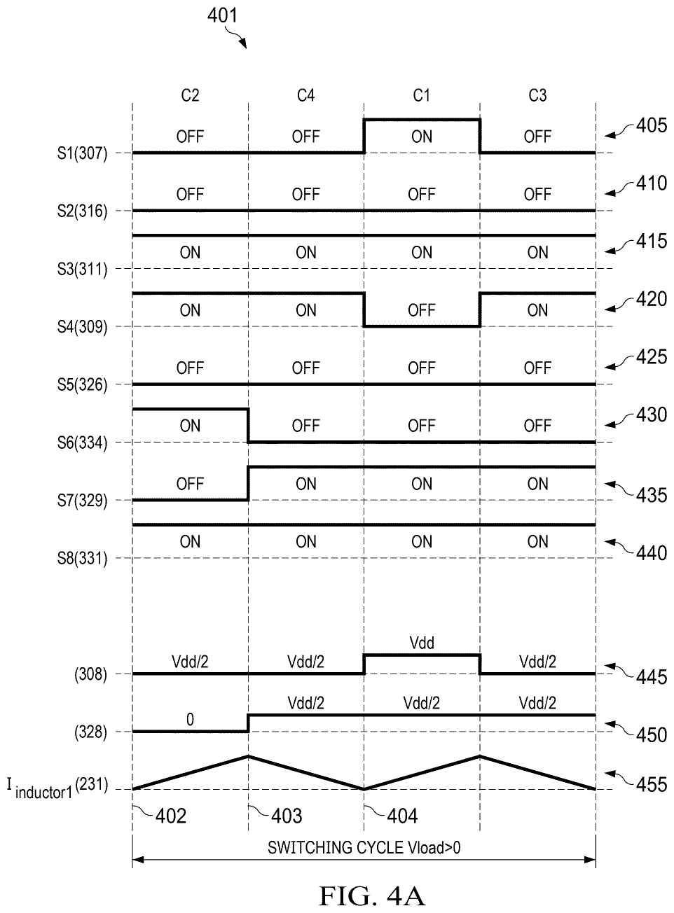

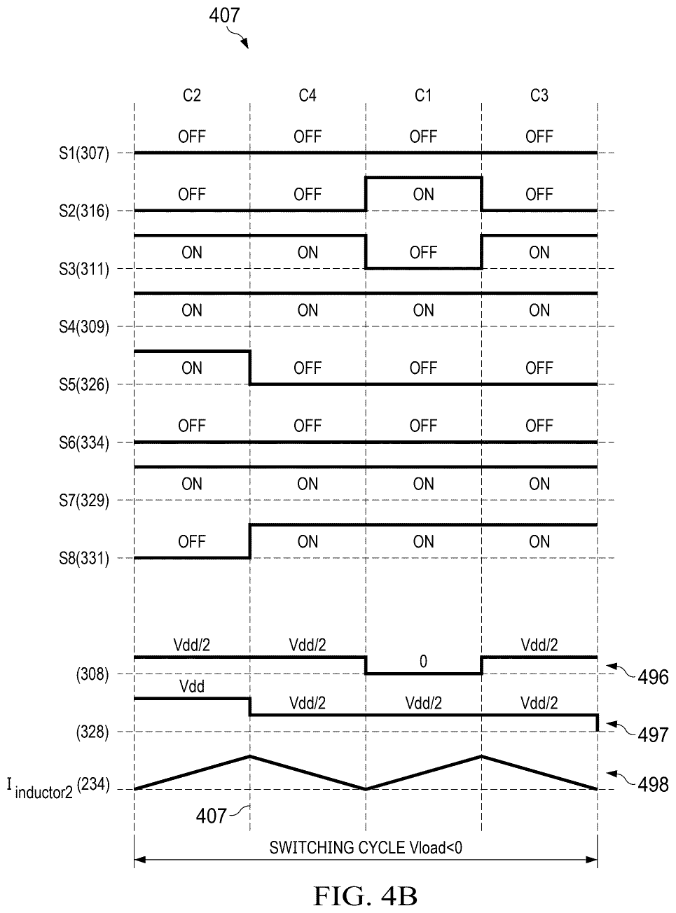

FIG. 4A shows a set of waveforms that may be present in the switching amplifier 300 in response to a first switching cycle of control signals (S1 through S8) applied to the switching amplifier 300 described above. More particularly, the first switching cycle corresponds to a condition where the first switch circuit 120 outputs a signal that causes a positive voltage to be present at the first terminal 151 of the speaker 140 shown in FIG. 3. The first switching cycle can include four distinct time periods each of which can be referred to as a pulse duration. In this example, the duty cycle of some of the control signals, such as S1 and S2, is less than 50%. In some other examples, first switching cycle can include “p” distinct time periods (p≥2) and a duty cycle of S1 and S2 control signals is larger than 50%.

The example set of waveforms 401 includes a first waveform 405 that includes a time period C1 where the control signal S1 that is provided to a driver 306 coupled to the FET 331 (shown in FIG. 3) places the FET 331 in an on condition. During the same time period C1, the control signal S2 that is provided to a driver 314 coupled to the FET 316 (shown in FIG. 3) places the FET 316 in an off condition (illustrated by the waveform 410). Waveform 415 illustrates a placement of FET 311 in an on condition via control signal S3 during the time period C1. Waveform 420 illustrates a placement of FET 309 in an off condition via control signal S4 during the time period C1. Placing FET 311 in an on condition and FET 309 in the off condition prevents current flow in the path from the positive drive terminal 308 and the intermediate voltage terminal V2 (intermediate connection point between the first capacitor 206 and the second capacitor 207 that is coupled in series with the first capacitor 206). Waveform 425 illustrates a placement of FET 326 in an off condition via control signal S5 during the time period C1. Waveform 430 illustrates a placement of the second FET 334 in an off condition via control signal S6 during the time period C1. Waveform 435 illustrates a placement of FET 329 in an on condition via control signal S7 during the time period C1. Waveform 440 illustrates a placement of FET 331 in an on condition via control signal S8 during the time period C1.

The placement of the various switches in the on/off conditions described above creates a path for current flow from the first terminal V1 (Vdd) to the intermediate voltage terminal V2. The current flow can occur via FET 307, low pass filter 130, low pass filter 135, FET 329 and FET 331.

Waveform 445 illustrates a voltage present at positive drive terminal 308 as a result of the current flow described above, and waveform 450 corresponds to a voltage present at the negative drive terminal 328 during the same time period C1. The voltage differential (Vdd−Vdd/2) between the voltage present at the positive drive terminal 308 and the voltage present at the negative drive terminal 328 creates a current flow (labeled as “Iinductor1 (231)”) through the low pass filter 130 and the low pass filter 135 during the time period C1. The current flow, which is illustrated by waveform 455, has an upwards slope starting at a point 404 in time where the previous time period C4 ends and the time period C1 begins.

The first waveform 405 further includes a time period C2 where the control signal S1 places the FET 307 in an off condition. During the same time period C2, the control signal S2 places the FET 316 in an off condition (illustrated by the waveform 410). Waveform 415 illustrates a placement of FET 311 in an on condition via control signal S3 during the time period C2. Waveform 420 illustrates a placement of FET 309 in an on condition via control signal S4 during the time period C2. Placing FET 311 and FET 309 in an on condition allows current flow in the path from the positive drive terminal 308 to the intermediate voltage terminal V2, to charge capacitors 206 and 207.

Waveform 425 illustrates a placement of FET 326 in an off condition via control signal S5 during the time period C2. Waveform 430 illustrates a placement of the second FET 334 in an on condition via control signal S6 during the time period C2. Waveform 435 illustrates a placement of FET 329 in an off condition via control signal S7 during the time period C2. Waveform 440 illustrates a placement of FET 331 in an on condition via control signal S8 during the time period C2.

The placement of the various switches in the on/off conditions described above creates a current path from the intermediate voltage terminal V2 to the third terminal V3 (ground/Vss), via FET 309, FET 311, low pass filter 130, low pass filter 135, and the second FET 334. By appropriately controlling the first switch circuit 120 and the second switch circuit 125 as described, the total charge drawn by the first switch circuit 120 from the capacitor 206 and the second switch circuit 125 from the capacitor 207 is the same, for the case where voltage of the first terminal 151 is higher than that of the second terminal 152. Since the charge flowing through the capacitors 206 and 207 is equal for both the charge and discharge phase, this ensures that the voltage at the intermediate voltage terminal V2 can be maintained/regulated at Vdd/2.

Waveform 445 further illustrates a voltage present at the positive drive terminal 308 and waveform 450 further illustrates a voltage present at the negative drive terminal 328 during the time period C2. The voltage differential (Vdd/2−0) between the voltage present at the positive drive terminal 308 and the voltage present at the negative drive terminal 328 causes a current flow through the low pass filter 130 and the low pass filter 135. The current flow has an upwards slope starting at a point 402 in time where a previous time period (not shown) ends and the time period C2 begins. The voltage differential at the point 403 in time corresponds to (Vdd/2−0).

The waveform characteristic of the Iinductor1 (231) current is based on the voltage differential at the positive drive terminal 308 fluctuating during the switching cycle, over a voltage range Vdd/2. The voltage range Vdd/2 is attributed to the voltage at the intermediate voltage terminal (the neural point voltage) being clamped at Vdd/2 by the charging and discharging of the pair of capacitors (capacitor 206 and capacitor 207 shown in FIG. 2 and FIG. 3) in accordance with the set of waveforms 401.

FIG. 4B shows a set of waveforms that may be present in the switching amplifier 300 in response to a second switching cycle of control signals (S1 through S8) applied to the switching amplifier 300 described above. More particularly, the second switching cycle corresponds to a condition where a voltage present at the first terminal 151 of the speaker 140 shown in FIG. 3 is a negative voltage with respect to the second terminal 152. The second switching cycle can include four distinct time periods that are identical to the ones described above with reference to the example set of waveforms 401. The description provided above with reference to placing various switches in an on condition and various other switches in an off condition is equally applicable to the set of example set of waveforms 407.

Referring to the time period C1, FET 316, FET 309, FET 329, and FET 331 are placed in an on condition and other switches are placed in an off condition. The placement of the various switches in such conditions creates a current path from the intermediate voltage terminal V2 to the third terminal V3 (ground/Vss), via FET 331, FET 329, low pass filter 135, low pass filter 130, and FET 316. Waveform 496 is at ground during the time period C1 and waveform 497 is at Vdd/2. The voltage differential (Vdd/2−0) between the voltage present at negative drive terminal 328 and the voltage present at positive drive terminal 308 creates a current flow (labeled as “Iinductor2 (234)” current) during C1 through the low pass filter 135 and the low pass filter 130.

Referring to the time period C2, FET 311, FET 309, FET 326, and FET 329 are placed in an on condition and other switches are placed in an off condition. The placement of the various switches in such conditions creates a current path from the first voltage terminal (Vss) to the intermediate voltage terminal V2, via FET 326, low pass filter 135, low pass filter 130, FET 311, and FET 309. Waveform 496 is at Vdd/2 and waveform 497 is at Vdd during the time period C2. The voltage differential (Vdd/2−Vdd) between the voltage present at negative drive terminal 328 and the voltage present at positive drive terminal 308 creates a current flow (Iinductor2 (234)) during C2 through the low pass filter 135 and the low pass filter 130.

Waveform 498 is substantially identical to waveform 455 and corresponds to the Iinductor2 (234) current flow which is in the opposite direction to the Iinductor1 (231) current flow indicated by the waveform 455.

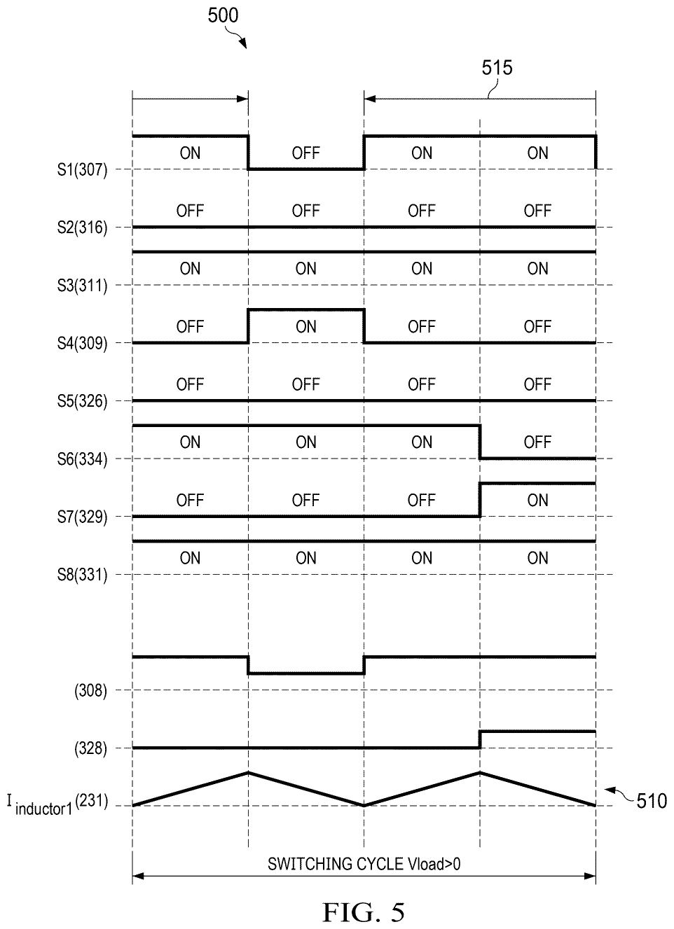

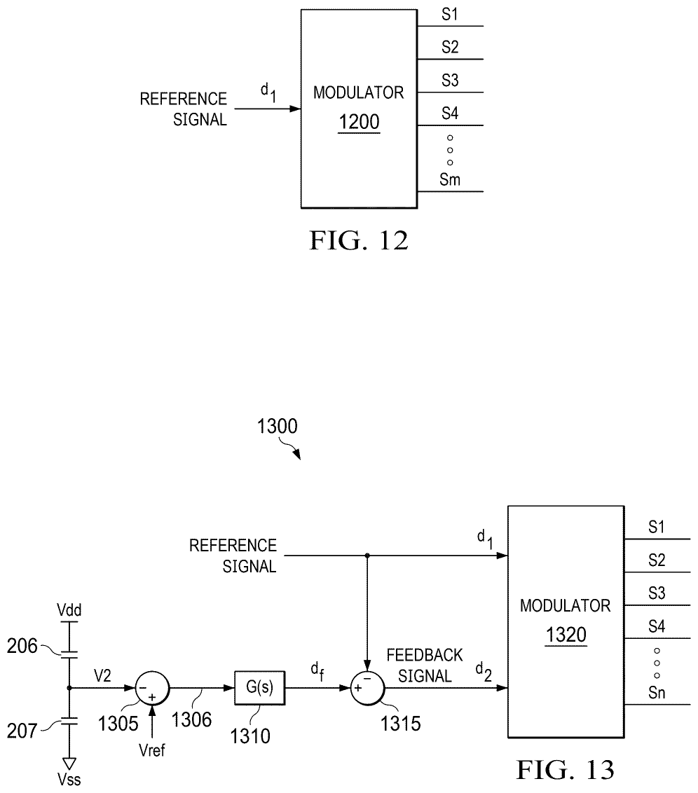

FIG. 5 shows another set of waveforms that may be present in the switching amplifier 300 in response to a first switching cycle of control signals (S1 through S8) applied to the switching amplifier 300 described above. The duty cycle of some of the control signals in this example exceeds 50%. More particularly, a time period 515 during which the control signal S1 places the FET 331 in an on condition is greater than the time period C1 that is described above with reference to FIG. 4A and FIG. 4B. The various control signals that are applied to the various switches can be generated by use of the duty cycle corresponding to the time period 515. This aspect is described below with reference to FIG. 12 that shows an example pulse width modulator circuit. The resulting the Iinductor1 (231) current depicted by waveform 510 is substantially identical to the Iinductor1 (231) current depicted by waveform 455 in FIG. 4A.

The waveform characteristic of the Iinductor1 (231) current depicted by waveform 510 is based on the voltage differential at the positive drive terminal 308 fluctuating over a voltage range Vdd/2, which constitutes the neutral point clamping voltage aspect provided by charging and discharging the pair of capacitors (capacitor 206 and capacitor 207 shown in FIG. 2 and FIG. 3) in accordance with the set of waveforms 500.

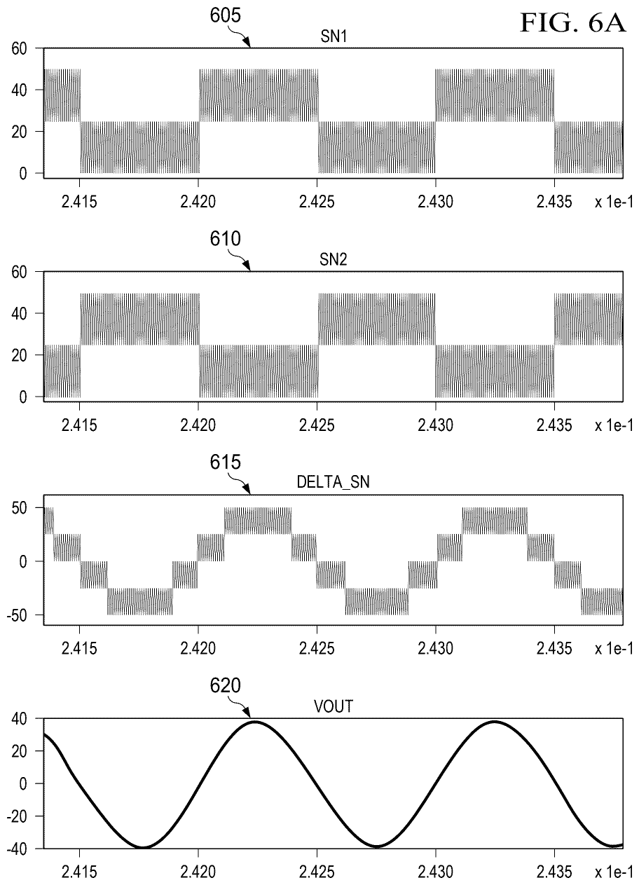

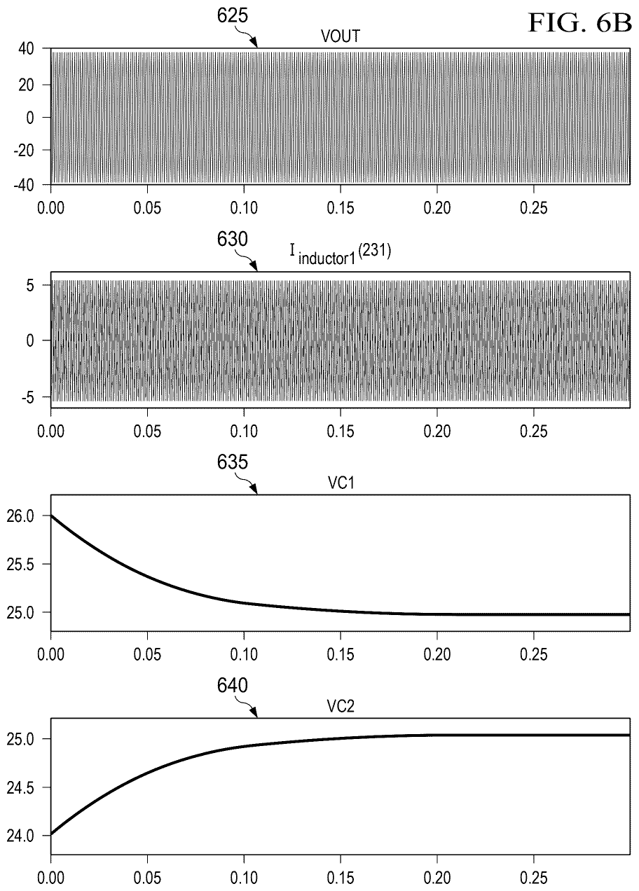

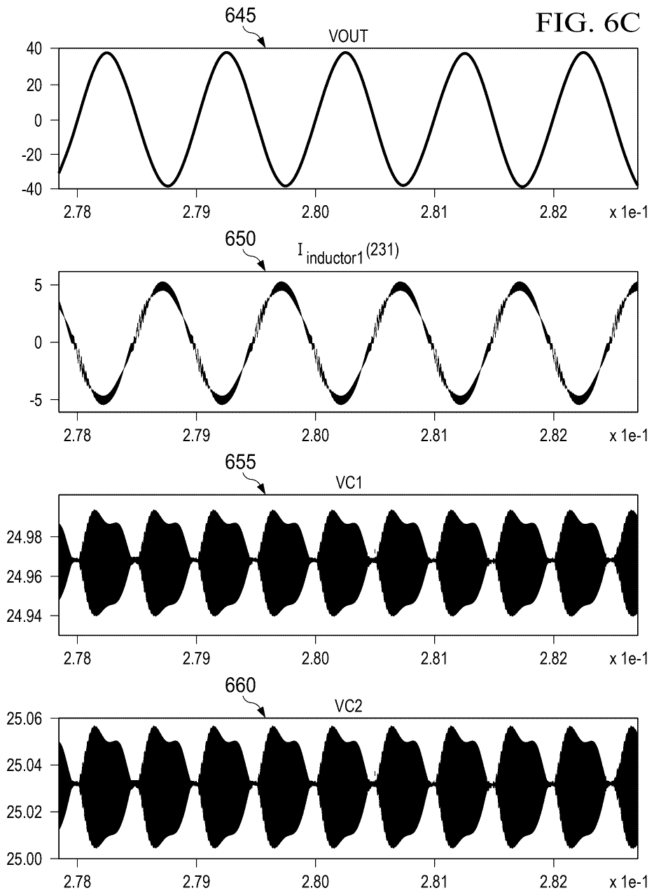

FIG. 6A shows a first set of example waveforms that may be present at various terminals of the switching amplifier 300 described above. More particularly, waveform 605 is an example tri-level modulated signal (SN1) that can be present at the positive drive terminal 308, responsive to a set of control inputs that are varied over time in a multi-cycle format. Waveform 610 is an example complementary tri-level modulated signal (SN2) that can be present at the negative drive terminal 328, responsive to the set of control inputs that are varied over time in a multi-cycle format. Waveform 615 represents a difference in voltage between the positive drive terminal 308 and the negative drive terminal 328 (Delta_SN) and waveform 620 (VOUT) represents a filtered version of the waveform 615 after low pass filtering by the low pass filter 130 and the low pass filter 135.

FIG. 6B shows another set of example waveforms that may be present at various terminals of the switching amplifier 300 described above. More particularly, waveform 625 (Vout) shows an example filtered signal that can be present at the first terminal 151 of the speaker 140. Waveform 630 shows the Iinductor1 (231) current when the filtered signal shown in waveform 625 is present at the first terminal 151 of the speaker 140. Assuming that a capacitance rating of the capacitor 206 is the same as a capacitance rating of the capacitor 207 and further assuming that an amount of initial charge stored in the capacitor 206 is different than an amount of initial charge stored in the capacitor 207, waveform 635 (VC1) and waveform 640 (VC2) illustrate a self-balancing characteristic of the switching amplifier 300 that causes the charge in the two capacitors to become balanced after a period of time.

FIG. 6C shows another set of example waveforms that may be present at various terminals of the switching amplifier 300 described above. More particularly, waveform 645 (Vout) shows a zoomed-in view of a portion of the waveform 625, waveform 650 (Iinductor1 (231) shows a zoomed-in view of a portion of the waveform 630, waveform 655 (VC1) shows a zoomed-in view of a portion of the waveform 635, and waveform 660 (VC2) shows a zoomed-in view of a portion of the waveform 640.

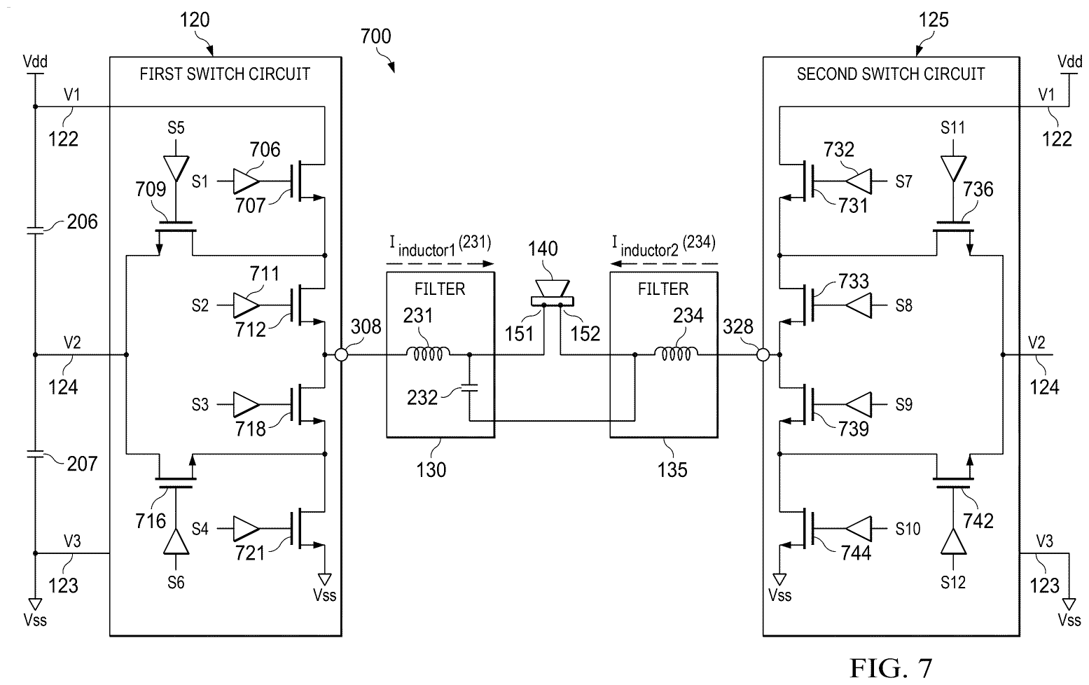

FIG. 7 is a schematic of a second example switching amplifier 700, which can be an example of switching amplifiers 100 and 200. The first switch circuit 120 and the second switch circuit 125 are configured to operate as a symmetric power stage of the switching amplifier 700. More particularly, the symmetric power stage is composed of the first switch circuit 120 coupled via the low pass filter 130 to the first terminal 151 of the speaker 140 and the second switch circuit 125 coupled via a second low pass filter 135 to the second terminal 152 of the speaker 140 in a symmetric arrangement with respect to the speaker. A first amplitude of a positive current flow through the speaker 140 from the first terminal 151 to the second terminal 152 in response to a first switching cycle of a control signal is substantially the same as a second amplitude of a negative current flow through the speaker 140 from the second terminal 152 to the first terminal 151 in response to a second switching cycle of the control signal. The balanced current flow through the speaker 140 during the two control cycles enables the pair of capacitors (capacitor 206 and capacitor 207) to provide neutral point clamping at an intermediate voltage over multiple switching cycles of the control signal.

In this implementation, the first switch circuit 120 includes a first set of transistors, which in this example, is a first set of FETs. Other types of transistors can be used in other implementations. The first set of transistors are configured to respond to a set of control signals (S1 through S6) that selectively place each transistor in the set of transistors in either an on state or an off state. The set of control inputs are varied over time in a multi-cycle format and the selective coupling of either V1 (Vdd), V2 (intermediate voltage), or V3 (Vss), by use of the multi-cycle control format, results in a tri-level modulated signal being output at the positive drive terminal 308.

In this example, the first switch circuit 120 includes a first pair of FETs coupled between the power supply terminal (Vdd) and the positive drive terminal 308; a second pair of FETs coupled between the reference terminal (Vss) and the positive drive terminal 308, and a third pair of FETs coupled between the intermediate voltage terminal (V2) and junction points in the first and second pair of transistors. More particularly, the first pair of FETs include a FET 707 connected in series with a FET 712. The series connection of the first pair of FETs comprises a drain terminal of the FET 707 connected to the power supply terminal (Vdd), a source terminal of the FET 707 connected to a drain terminal of FET 712, and a source terminal of the FET 712 connected to the positive drive terminal 308. The second pair of FETs include a FET 718 connected in series with a FET 721. The series connection of the second pair of FETs comprises a drain terminal of the FET 718 connected to the positive drive terminal 308, a source terminal of the FET 718 connected to a drain terminal of FET 721, and a source terminal of the FET 721 connected to the reference terminal (Vss). The third pair of FETs include a FET 709 and a FET 716. A drain terminal of the FET 709 is connected to the source terminal of the FET 707 (and the drain terminal of the FET 712). A source terminal of the FET 709 is connected to a drain terminal of the FET 716. A source terminal of the FET 716 is connected to a source terminal of the FET 718 (and the drain terminal of the FET 721).

The second switch circuit 125 includes a second set of transistors, which in this example, is a second set of FETs. Other types of transistors can be used in other implementations. The second set of transistors are configured to respond to another set of control signals (S7 through S12) that selectively place each transistor in either an on state or an off state. The set of control inputs are varied over time in a multi-cycle format and the selective coupling of either V1 (Vdd), V2 (intermediate voltage), or V3 (Vss), by use of the multi-cycle control format, results in a tri-level modulated signal being output at the negative drive terminal 328.

More particularly, in this example, the second switch circuit 125 includes a first pair of FETs coupled between the power supply terminal (Vdd) and the negative drive terminal 328; a second pair of FETs coupled between the reference terminal (Vss) and the negative drive terminal 328, and a third pair of FETs coupled between the intermediate voltage terminal (V2) and junction points in the first and second pair of transistors. More particularly, the first pair of FETs include a FET 731 connected in series with a FET 733. The series connection of the first pair of FETs comprises a drain terminal of the FET 731 connected to the power supply terminal (Vdd), a source terminal of the FET 731 connected to drain terminal of FET 733, and a source terminal of the FET 733 connected to the negative drive terminal 328. The second pair of FETs include a FET 739 connected in series with a FET 744. The series connection of the second pair of FETs comprises a drain terminal of the FET 739 connected to the negative drive terminal 328, a source terminal of the FET 739 connected to a drain terminal of FET 744, and a source terminal of the FET 744 connected to the reference terminal (Vss). The third pair of FETs include a FET 736 and a FET 742. A drain terminal of the FET 736 is connected to the source terminal of the FET 731 (and the drain terminal of the FET 733). A source terminal of the FET 736 is connected to a drain terminal of the FET 742. A source terminal of the FET 742 is connected to a source terminal of the FET 739 (and the drain terminal of the FET 744).

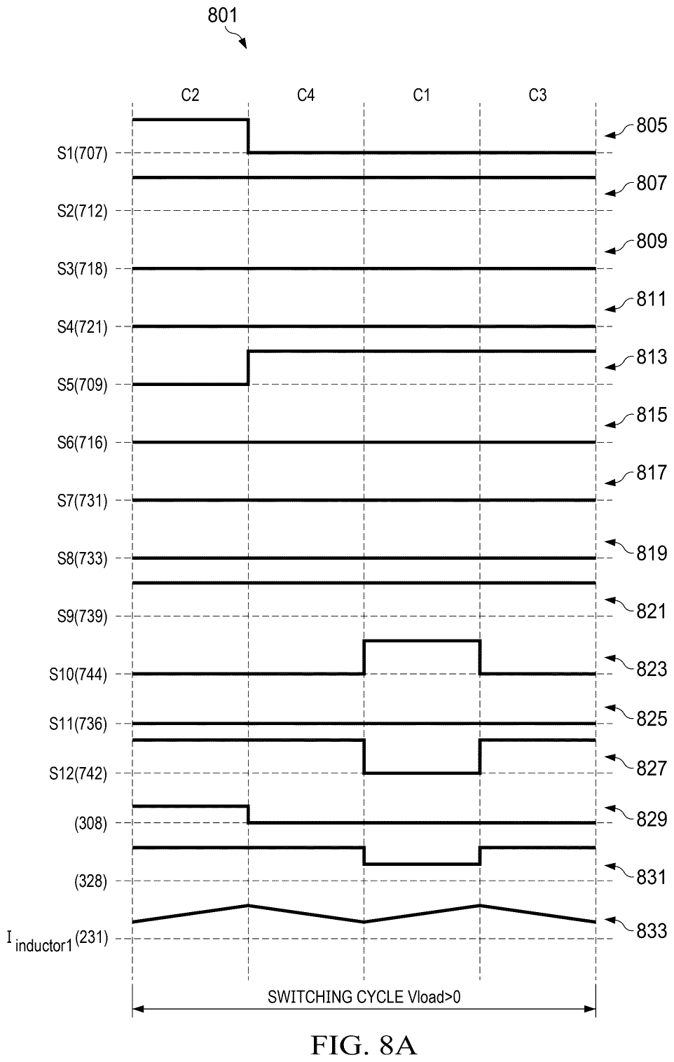

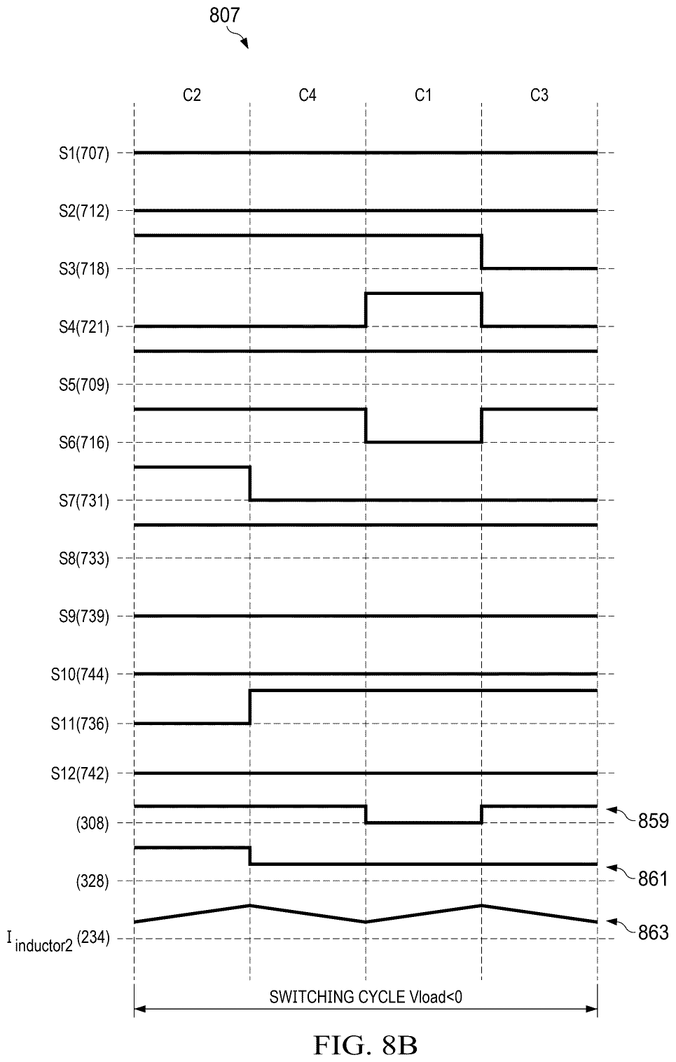

An example set of waveforms corresponding to operations pertaining to varying control inputs S1 through S4 of the first switch circuit 120 and S7 though S12 of the second switch circuit 125, in the multi-cycle format, is described below with reference to FIG. 8A and FIG. 8B. The tri-level modulated signal output at the positive drive terminal 308 may allow for a reduction in size of the inductor 231 in the low pass filter 130. The reduction in size is in comparison to a size of an inductor that is a part of a low pass filter used for filtering a two-level (binary) modulated signal. The tri-level modulated signal output at the negative drive terminal 328 may allow for a reduction in size of the inductor 234 in the low pass filter 135. Again, the reduction in size is in comparison to a size of an inductor that is a part of a low pass filter used for filtering a two-level (binary) modulated signal.

FIG. 8A shows a set of example set of waveforms 801 corresponding to a first switching cycle of control signals that can be used in the switching amplifier 700 described above with reference to FIG. 7. More particularly, the first switching cycle corresponds to a condition where a voltage present at the first terminal 151 of the speaker 140 shown in FIG. 3 is a positive voltage with respect to the second terminal 152. The first switching cycle can include four distinct time periods each of which can be referred to as a pulse duration or as a part of a duty cycle. In this example, the duty cycle is a 50% duty cycle. The example set of waveforms 801 includes a first waveform 805 that includes a time period C1 where the control signal S1 that is provided to a driver 706 coupled to the FET 707 (shown in FIG. 7) places the FET 707 in an off condition. During the same time period C1, the control signal S2 that is provided to a driver 711 coupled to the FET 732 (shown in FIG. 7) places the FET 732 in an on condition (illustrated by the waveform 807). Waveform 809 illustrates a placement of FET 718 in an off condition via control signal S3 during the time period C1. Waveform 811 illustrates a placement of FET 721 in an off condition via control signal S4 during the time period C1. Waveform 813 illustrates a placement of FET 709 in an on condition via control signal S5 during the time period C1. Waveform 815 illustrates a placement of FET 716 in an off condition via control signal S6 during the time period C1. Waveform 817 illustrates a placement of FET 731 in an off condition via control signal S7 during the time period C1. Waveform 819 illustrates a placement of FET 733 in an off condition via control signal S8 during the time period C1. Waveform 821 illustrates a placement of FET 739 in an on condition via control signal S9 during the time period C1. Waveform 823 illustrates a placement of FET 744 in an off condition via control signal S10 during the time period C1. Waveform 825 illustrates a placement of FET 736 in an off condition via control signal S11 during the time period C1. Waveform 827 illustrates a placement of FET 742 in an off condition via control signal S12 during the time period C1.

Placing the various FETs in the on/off conditions described above creates a current path from the intermediate voltage terminal V2 to the reference terminal (Vss) via FET 709, FET 712, low pass filter 130, low pass filter 135, FET 739, and FET 744.

Waveform 829 illustrates a voltage present at positive drive terminal 308 and waveform 831 corresponds to a voltage present at negative drive terminal 328 during the time period C1 (as illustrated in FIG. 8A). The voltage differential (Vdd/2−0) between the voltage present at positive drive terminal 308 and the voltage present at negative drive terminal 328 during C1 creates a current flow (labeled as a Iinductor1 (231)) through the low pass filter 130 and the low pass filter 135. The current flow, which is illustrated by waveform 833, has an upwards slope starting at a point in time where the previous time period C4 ends and the time period C1 begins.

The first waveform 805 further includes a time period C2 where the control signal S1 places the FET 707 in an on condition. During the same time period C2, the control signal S2 places the FET 712 in an on condition as illustrated in the waveform 807. Waveform 809 illustrates a placement of FET 718 in an off condition via control signal S3 during the time period C2. Waveform 811 illustrates a placement of FET 721 in an off condition via control signal S4 during the time period C2. Waveform 813 illustrates a placement of FET 709 in an off condition via control signal S5 during the time period C2. Waveform 815 illustrates a placement of FET 716 in an off condition via control signal S6 during the time period C2. Waveform 817 illustrates a placement of FET 731 in an off condition via control signal S7 during the time period C2. Waveform 819 illustrates a placement of FET 733 in an off condition via control signal S8 during the time period C2. Waveform 821 illustrates a placement of FET 739 in an on condition via control signal S9 during the time period C2. Waveform 823 illustrates a placement of FET 744 in an off condition via control signal S10 during the time period C2. Waveform 825 illustrates a placement of FET 736 in an off condition via control signal S11 during the time period C2. Waveform 827 illustrates a placement of FET 742 in an on condition via control signal S12 during the time period C2.

Placing the various FETs in the on/off conditions described above creates a current path from the power supply terminal (Vdd) to the intermediate voltage terminal V2 via FET 707, FET 712, low pass filter 130, low pass filter 135, FET 739, and FET 742, to charge capacitors 206 and 207.

Waveform 829 illustrates a voltage present at positive drive terminal 308 and waveform 831 corresponds to a voltage present at negative drive terminal 328 during the time period C1 (as illustrated in FIG. 8A). The voltage differential (Vdd−Vdd/2) between the voltage present at positive drive terminal 308 and the voltage present at negative drive terminal 328 during C2 creates a current flow (labeled as Iinductor1 (231) current) through the low pass filter 130 and the low pass filter 135. The current flow, which is illustrated by waveform 833, has an upwards slope starting at a point in time where the previous time period ends and the time period C2 begins.

FIG. 8B shows a set of example set of waveforms 807 corresponding to a second switching cycle of control signals that can be used in the switching amplifier 700 described above. More particularly, the second switching cycle corresponds to a condition where a voltage present at the first terminal 151 of the speaker 140 shown in FIG. 3 is a negative voltage with respect to the second terminal 152. The second switching cycle can include four distinct time periods that are identical to the ones described above with reference to the example set of waveforms 801. The description provided above with reference to placing various switches in an on condition and various other switches in an off condition is equally applicable to the set of example set of waveforms 807.

Referring to the time period C1, FET 736, FET 733, FET 718, and FET 721 are placed in an on condition and other switches are placed in an off condition. The placement of the various switches in such conditions creates a current path from the intermediate voltage terminal V2 to the reference terminal (Vss) via FET 736, FET 733, low pass filter 130, low pass filter 135, FET 718 and FET 721. By appropriately controlling the first switch circuit 120 and the second switch circuit 125 as described, the total charge drawn by the first switch circuit 120 from the capacitor 206 and the second switch circuit 125 from the capacitor 207 is the same, for the case where voltage of first terminal 151 is lower than that of second terminal 152. Since the charge flowing through the capacitors 206 and 207 is equal for both the charge and discharge phase, this ensures that the voltage at the intermediate voltage terminal V2 can be maintained/regulated at Vdd/2.

Referring to the time period C2, FET 731, FET 733, FET 718, and FET 716 are placed in an on condition and other switches are placed in an off condition. The placement of the various switches in such conditions creates a current path from the first voltage terminal V1 (Vss) to the intermediate voltage terminal V2, via FET 731, FET 733, low pass filter 135, low pass filter 130, FET 718, and FET 716. Waveform 859 is at Vdd/2 and waveform 861 is at Vdd during the time period C2. The voltage differential (Vdd−Vdd/2) between the voltage present at negative drive terminal 328 and the voltage present at positive drive terminal 308 creates a current flow (labeled as a Iinductor2 (234)) during C2 through the low pass filter 135 and the low pass filter 130.

Waveform 863 is substantially identical to waveform 833 and corresponds to the Iinductor2 (234) current flow which is in the opposite direction to the Iinductor1 (231) flow indicated by the waveform 833.

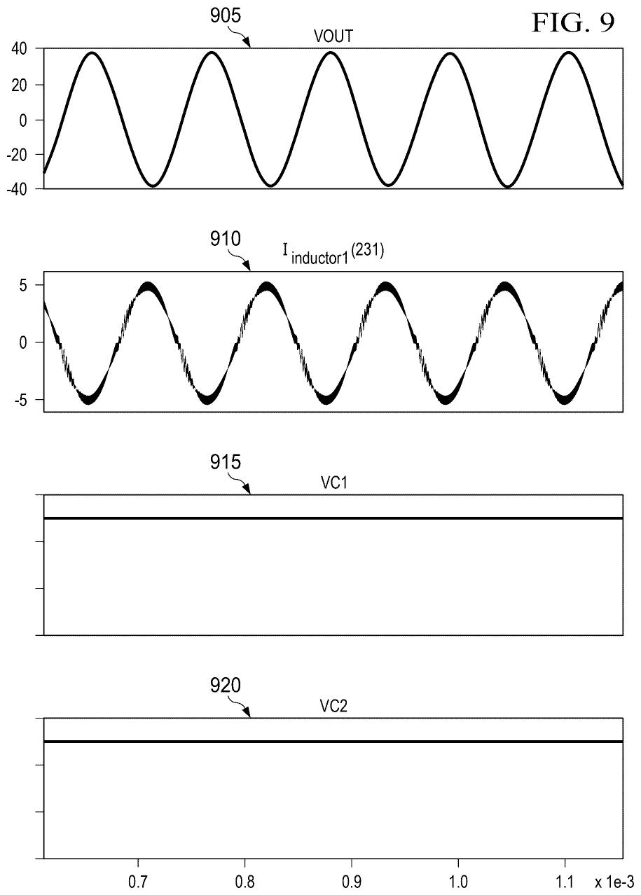

FIG. 9 shows another set of example waveforms that may be present at various terminals of the switching amplifier 700 described above. More particularly, waveform 905 (Vout) shows a zoomed-in view of a portion of an example filtered signal that can be present at the first terminal 151 of the speaker 140. Waveform 910 (Iinductor1 (231) shows a zoomed-in view of a portion of an example filtered signal that can be present at the first terminal 151 of the speaker 140. Waveform 915 (VC1) and waveform 920 (VC2) illustrate a self-balancing characteristic of the switching amplifier 700 that causes the charge in the capacitor 206 and the capacitor 207 to become balanced after a period of time. This charge balancing feature is identical to the charge balancing feature described above with reference to FIG. 6B and the switching amplifier 300.

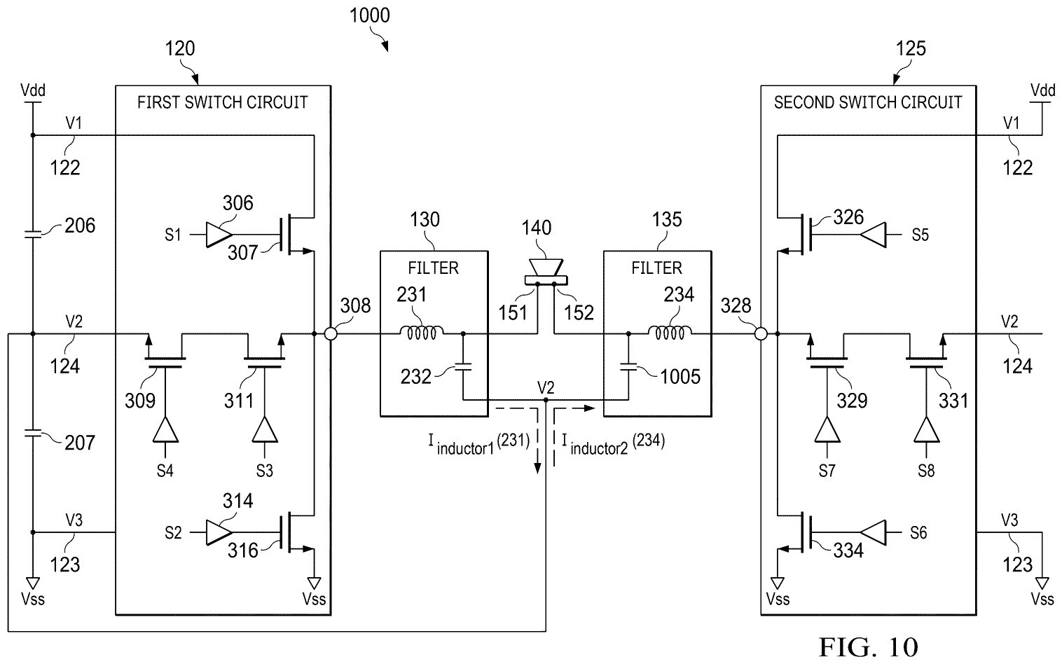

FIG. 10 is a schematic of a third example switching amplifier 1000, which can be an example of switching amplifiers 100 and 200. The third example is substantially identical to the switching amplifier 300 described above with reference to FIG. 3, and with each of the capacitor 232 of the low pass filter 130 and a capacitor 1005 of the low pass filter 135 referenced to the intermediate voltage (V2). More particularly, capacitor 232 has one terminal connected to first terminal 151 of the speaker 140 and another terminal connected to the intermediate voltage terminal 124 and capacitor 1005 has one terminal connected to second terminal 152 of the speaker 140 and another terminal connected to the intermediate voltage terminal (V2). The connection arrangement of the capacitor 232 and the capacitor 1005 may be provided in at least some implementations in order to reduce or eliminate adverse effects of electromagnetic interference (EMI) on the audio output of the speaker 140. Furthermore, the capacitor 232 may be located close to the first terminal 151 of the speaker 140 and the capacitor 1005 may be located close to the second terminal 152 of the speaker 140 in order to reduce common-mode EMI when each of a pair of wires used to connect the low pass filter 130 to the first terminal 151 of the speaker 140 and to connect the low pass filter 135 to the second terminal 152 of the speaker 140 is long and susceptible to EMI pickup.

The current flows through the low pass filter 130 to the intermediate voltage terminal (V2) and from the intermediate voltage terminal (V2) and through the low pass filter 135 are shown by dashed arrows.

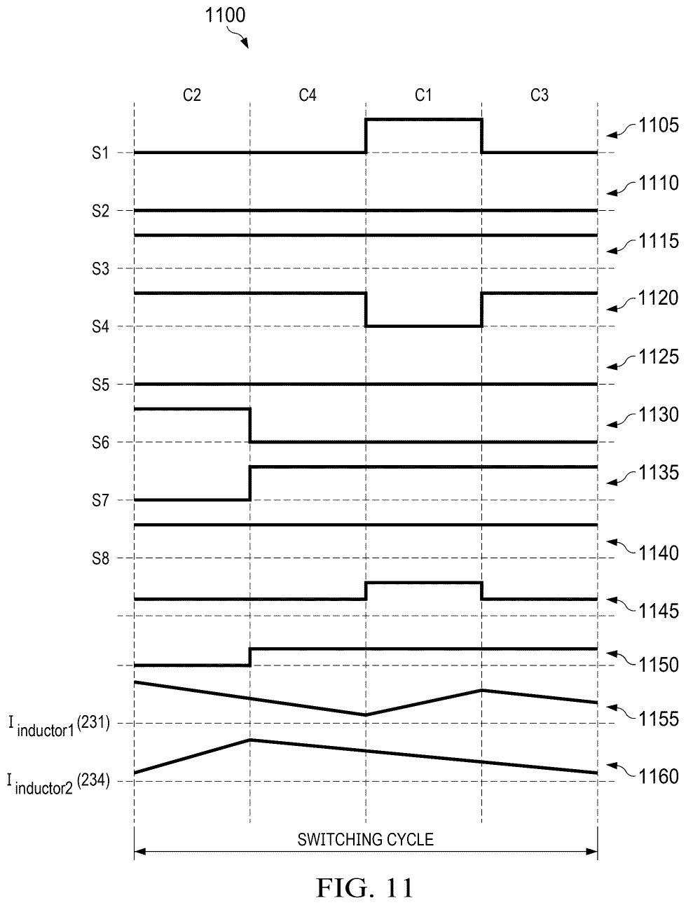

FIG. 11 shows a set of waveforms corresponding to the switching amplifier 1000 shown in FIG. 10 and described above. As indicated above, switching amplifier 1000 shown in FIG. 10 substantially identical to the switching amplifier 300 shown in FIG. 3, with the exception that each of the capacitor 232 of the low pass filter 130 and a capacitor 1005 of the low pass filter 135 is referenced to the intermediate voltage (V2). A subset of the waveforms shown in FIG. 4A, which correspond to a first switching cycle of control signals that can be used for operating the switching amplifier 300 described above, is substantially identical to a subset of waveforms in the set of waveforms 1100 that correspond to a first switching cycle of control signals that can be used for operating the switching amplifier 1000 shown in FIG. 10. The first switching cycle corresponds to a condition where a voltage present at the first terminal 151 of the speaker 140 shown in FIG. 3 is a positive voltage with respect to the second terminal 152.

The subset of waveforms in FIG. 4A correspond to control signals S2 through S8, and the equivalent subset of waveforms in FIG. 11 correspond to the same control signals S2 through S8 (waveform 1105, waveform 1110, waveform 1115, waveform 1120, waveform 1125, waveform 1130, waveform 1135, and waveform 1140). The subset of waveforms in FIG. 4A further includes waveform 445, which illustrates a voltage present at positive drive terminal 308 and waveform 450 that corresponds to a voltage present at negative drive terminal 328 during the switching cycle. The correspondingly identical subset of waveforms in FIG. 11 includes waveform 1145, which illustrates a voltage present at positive drive terminal 308, and waveform 1150 that corresponds to a voltage present at negative drive terminal 328 during the switching cycle.

Providing the additional capacitor 1005 in the switching amplifier 1000 shown in FIG. 10 and connecting the common node of capacitor 232 and capacitor 1005 to voltage V2, which is not included in the switching amplifier 300 shown in FIG. 3, causes a change in the individual inductor currents in the switching amplifier 1000. More particularly, waveform 1155 represents the inductor current Iinductor1 (231) shown in FIG. 10 corresponding to a condition where a voltage present at the first terminal 151 of the speaker 140 shown in FIG. 3 is a positive voltage. Waveform 1160 represents the inductor current Iinductor2 (234) corresponding to a condition where a voltage present at the first terminal 151 of the speaker 140 shown in FIG. 3 is a positive voltage. The slope of the charge and discharge cycles are affected due to the addition of the capacitor 1005 and the connection of the common node of the capacitors to the voltage V2 in the switching amplifier 1000.

FIG. 12 shows an example of a modulator 1200 that can be included in any one or more of the switching amplifiers described above. For example, the modulator 1200 may be included in the control circuit 215 shown in FIG. 2. The modulator 1200 can be used to generate some or all of control signals S1 through Sm that are shown in the example switching amplifier 200. The input to the modulator 1200 can be a reference signal “d1” that can correspond to one of “p” time periods in a switching cycle of control signals. For example, the reference signal can have a pulse width that corresponds to a time period C1 or a time period C2 that are referred to above with respect to various figures.

FIG. 13 shows an example modulator circuit 1300 that can be included in any one or more of the switching amplifiers described above. For example, the modulator circuit 1300 may be included in the control circuit 215 shown in FIG. 2. The modulator circuit 1300 can be used to generate some or all of control signals S1 through Sm that are shown in the example switching amplifier 200. The modulator circuit 1300 can include a modulator 1320 that is configured to operate in cooperation with other elements in a feedback configuration that allows for dynamically varying a pulse width of some or all of control signals S1 through Sm in response to variations in the intermediate voltage V2. More particularly, the modulator 1320 can be a pulse width modulator and it responds to a combination of two inputs-a reference signal input having a fixed pulse width “d1” and a feedback signal having a variable pulse width “d2.”

In this example, the feedback signal is derived by use of a circuit that includes a mixer 1305 and a function generator 1310 or compensator. A first input to the mixer 1305 is the intermediate voltage V2 and a second input is a reference voltage Vref. The reference voltage Vref is selected to correspond to a desired intermediate voltage for the switching amplifier. For example, the reference voltage Vref may be set to Vdd/2 to correspond to a desired intermediate voltage of Vdd/2. The intermediate voltage V2 at the interconnection of the capacitor 206 and the capacitor 207 can vary due to various factors. One example factor is a difference or change in the characteristics of the capacitor 206 and/or the capacitor 207, which can lead to V2 being different than Vref. An example difference between the capacitor 206 and the capacitor 207 pertains to a capacitance value. For example, in an example, the capacitor 206 may be a 10 μF capacitor and the capacitor 207 may be a 15 μF capacitor. Another example characteristic of the capacitor 206 and the capacitor 207 that can lead to the difference may pertain to a tolerance parameter. Another example characteristic of the capacitor 206 and the capacitor 207 may pertain to a performance difference over environmental conditions (temperature, humidity, etc.). Another example characteristic of the capacitor 206 and the capacitor 207 may be attributable to different aging effects on the two capacitors.

In an example operating scenario, V2 may be slightly higher than Vdd/2 (for example, by 5%). In this case, the output of the mixer 1305 (line 1306) can be equal to the 5% voltage difference. The voltage on line 1306 is coupled into the function generator 1310, which produces an output signal having a pulse width “df” that is a function of the voltage on line 1306. The output of another mixer 1315 is a feedback signal having a pulse width d2 that is equal to (d1−df). The modulator 1320 modifies one or more of the control signals S1 through Sm in response to detecting a difference between d1 and d2. The modified control signals may lead to a change in V2, thereby leading to a reduction (movement towards zero) of the voltage on line 1306.

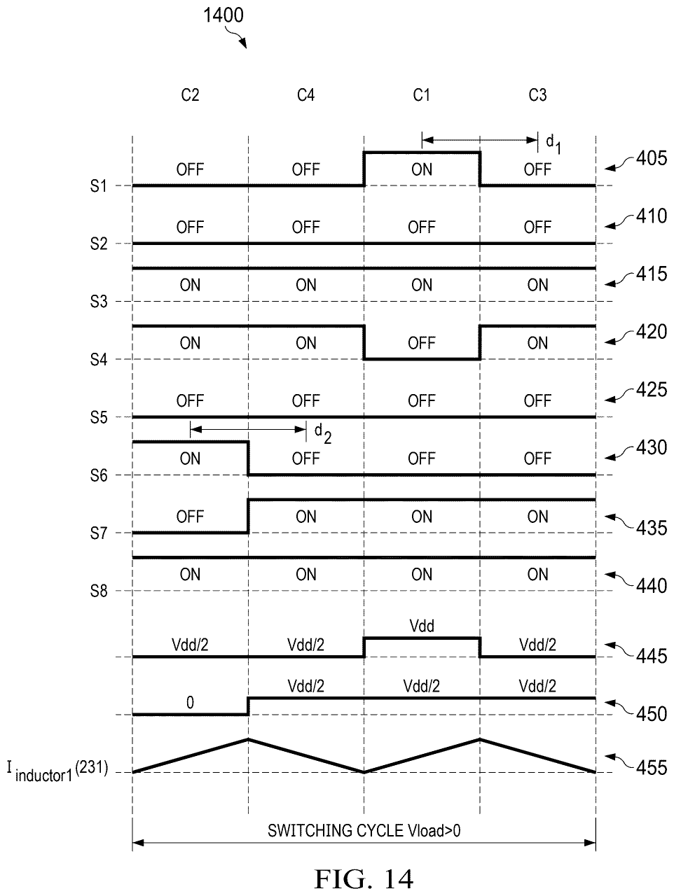

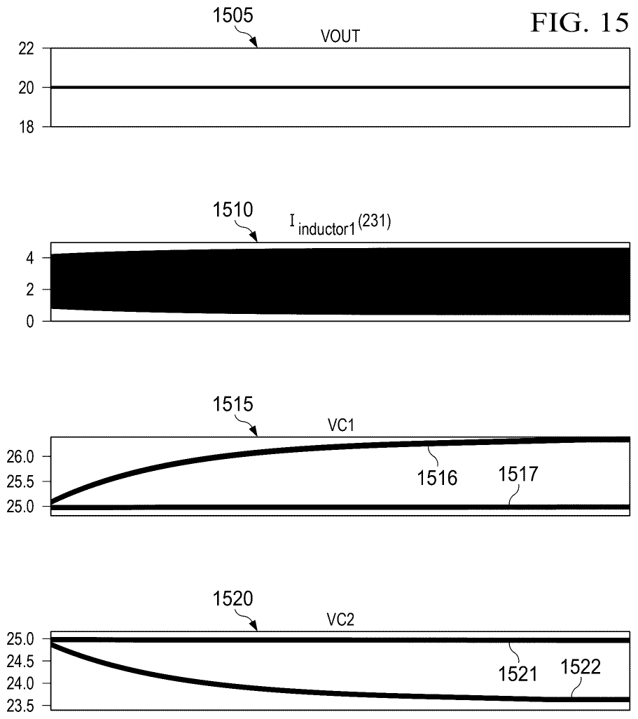

FIG. 14 shows an example set of waveforms 1400 that is a replica of the set of waveforms 401 shown in FIG. 4A. The set of waveforms 1400 is shown for purposes of describing an operation of the modulator circuit 1300 described above. As indicated above, the modulator circuit 1300 may modify one or more of the control signals S1 through Sm in response to detecting a difference between d1 and d2. In this example, modification of the control signals S1 through Sm can include modifying a pulse width of one or more pulses.

As indicated above, a difference in capacitance value between the capacitor 206 and the capacitor 207 can cause the intermediate voltage V2 to be different than Vref shown in FIG. 13. The modulator 1320 modifies one or more of the control signals S1 through Sm in response to detecting a difference between d1 and d2. In one example, where the capacitor 206 is a 10 μF capacitor and the capacitor 207 is a 15 μF capacitor, the modulator 1320 may modify control signal S1 and control signal S6 for example. The modification of the control signal S1 during the time period C1 may involve a modification of a pulse width “d1” of a pulse in the waveform 405, during the time period C1. For example, the modification of the pulse width can involve an increase in pulse width. The modification of the control signal S6 may involve a modification of a pulse width “d2” of a pulse in the waveform 430, during the time period C2. For example, the modification of the pulse width “d2” during the time period C2 can involve a decrease in pulse width. The increase/decrease in pulse widths may be proportional to the difference in capacitance value between the capacitor 206 and the capacitor 207.

FIG. 15 shows some waveforms that may be associated with the modulator circuit 1300 shown in FIG. 13 and described above with further reference to FIG. 14. Waveform 1505 show an output voltage that may be present at the positive drive terminal 308. Waveform 1510 shows an inductor current Iinductor1 (231).

Waveform 1515 shows a pair of voltage curves for the capacitor 206 for comparison of a performance characteristic of the capacitor 206 with and without use of a feedback circuit. More particularly, the voltage curve 1516 shows a characteristic of the capacitor 206 when no feedback is applied such as, for example, by use of the pulse width modulator shown in FIG. 12. The voltage curve 1517 shows a voltage characteristic of the capacitor 206 when feedback is applied, such as, for example, when the pulse width modulator shown in FIG. 13 is included. The corrective action obtained by use of feedback is illustrated by voltage curve 1517 which indicates a relative stable voltage over the control cycle period.

Waveform 1520 shows a pair of voltage curves for the capacitor 207 for comparison of a performance characteristic of the capacitor 207 with and without use of a feedback circuit. More particularly, the voltage curve 1522 shows a characteristic of the capacitor 207 when no feedback is applied such as, for example, by use of the pulse width modulator shown in FIG. 12. The voltage curve 1521 shows a voltage characteristic of the capacitor 206 when feedback is applied, such as, for example, when the pulse width modulator shown in FIG. 13 is included. The corrective action obtained by use of feedback is illustrated by voltage curve 1521 which indicates a relative stable voltage over the control cycle period.

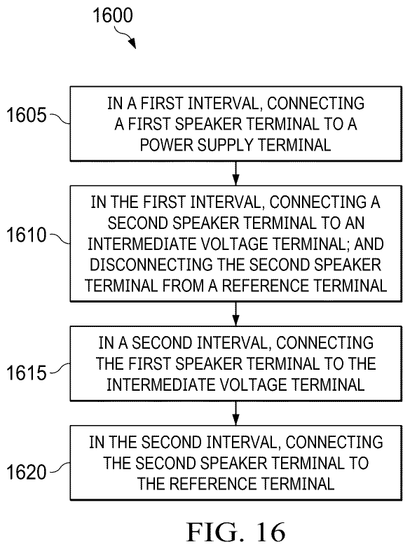

FIG. 16 shows a flowchart of a method of operation of a switching amplifier, such as the examples of switching amplifier described here in. The switching amplifier may be a class D amplifier. Other sequences of operations can also be performed to operate a switching amplifier according to alternative examples. For example, alternative examples may perform the operations in a different order. Moreover, the individual operations illustrated in FIG. 16 can include multiple sub-operations that can be performed in various sequences as appropriate for the individual operation. Furthermore, some operations can be added or removed depending on the particular example. In some examples, two or more operations may be performed in parallel. In some examples, two or more operations in flowchart 1600 may be performed iteratively. One of ordinary skill in the art would recognize many variations, modifications, and alternatives.

An operation indicated at block 1605 of flowchart 1600 may include connecting a first speaker terminal to a power supply terminal in a first interval. Using the first example switching amplifier 300 shown in FIG. 3, as one example, the operation indicated at block 1605 of flowchart 1600 may include connecting the first terminal 151 of the speaker 140 to a Vdd terminal in a first interval C1 as illustrated in FIG. 4A. This operation may be carried out by placing FET 307 in an on state (as illustrated in waveform 405).

At block 1610, an operation may involve connecting a second speaker terminal to an intermediate voltage terminal and disconnecting the second speaker terminal from a reference terminal. Using the first example switching amplifier 300 shown in FIG. 3, as one example, the operation indicated at block 1610 of flowchart 1600 may include connecting the second terminal 152 to the intermediate voltage terminal V2 and disconnecting the second terminal 152 from Vss, in a first interval C1 as illustrated in FIG. 4A. This operation may be carried out by placing each of FET 329 and FET 331 in an on state during C1 (as illustrated in waveform 435 and waveform 440) for connecting the second terminal 152 to the intermediate voltage terminal V2 and by placing FET 334 in an off state for disconnecting the second terminal 152 from Vss.

At block 1615, an operation may involve connecting the first speaker terminal to an intermediate voltage terminal in a second interval. Using the first example switching amplifier 300 shown in FIG. 3, as one example, the operation indicated at block 1615 of flowchart 1600 may include connecting the first terminal 151 of the speaker 140 to the intermediate voltage terminal V2 in the second interval C2. This operation may be carried out by placing FET 309 and FET 311 in an on condition (as illustrated in waveform 415 and waveform 420 in FIG. 4A).

At block 1620, an operation may involve connecting the second speaker terminal to the reference terminal in the second interval. Using the first example switching amplifier 300 shown in FIG. 3, as one example, the operation indicated at block 1620 of flowchart 1600 may include connecting the second terminal 152 to Vss in the second interval C2. This operation may be carried out by placing FET 334 in an on condition (as illustrated in waveform 430 in FIG. 4A).

References herein to a FET being “on” or “enabled” means that the conduction channel of the FET is present and drain current may flow through the FET. References herein to a FET being “off” or “disabled” means that the conduction channel is not present so drain current does not flow through the FET. An “off” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “reference,” “reference terminal,” or “ground” in the foregoing description include a chassis ground, an Earth ground, a floating ground, a virtual ground, a digital ground, a common ground, and/or any other form of ground connection applicable to, or suitable for, the teachings of this description. In some implementations, the reference terminal may be connected to a negative power supply in lieu of ground.

In this description, unless otherwise stated, “about,” “approximately” or “substantially” preceding a parameter means being within +/−10 percent of that parameter or, if the parameter is zero, a reasonable range of values around zero.

Terms “and” and “or,” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean A, B, C, or a combination of A, B, and/or C, such as AB, AC, BC, AA, ABC, AAB, ACC, AABBCCC, or the like.

Although various examples have been described in detail, it should be understood that various changes, substitutions, and alterations can be made therein without departing from the scope defined by the appended claims. The devices, structures, materials, and processes discussed above are examples. Various examples may omit, substitute, or add various procedures or components as appropriate. Also, features described with respect to certain examples may be combined in various other examples. Different aspects and elements of the examples may be combined in a similar manner. Also, technology evolves and, thus, many of the elements are examples that do not limit the scope of the disclosure to those specific examples.

Specific details are given in the description on order to provide a thorough understanding of the examples. However, examples may be practiced without these specific details. For example, well-known circuits, processes, systems, structures, and techniques may have been shown without unnecessary detail in order to avoid obscuring the examples. This description provides examples only, and is not intended to limit the scope, applicability, or configuration of the invention. Rather, the preceding description of the examples will provide those skilled in the art with an enabling description for implementing various examples. Various changes may be made in the function and arrangement of elements without departing from the spirit and scope of the present disclosure. Modifications are possible in the described examples, and other examples are possible, within the scope of the claims.

What is claimed is:

1. An apparatus comprising:
a set of terminals including a power supply terminal, a reference terminal, and an intermediate voltage terminal;
a first switch circuit coupled to the set of terminals and including a first set of control inputs and a positive drive terminal, wherein the first switch circuit is configured to, responsive to a first set of control signals applied to the first set of control inputs, selectively couple a first terminal of the set of terminals to the positive drive terminal; and
a second switch circuit coupled to the set of terminals and including a second set of control inputs and a negative drive terminal, wherein the second switch circuit is configured to, responsive to a second set of control signals applied to the second set of control inputs, selectively couple one of the first terminal or a second terminal of the set of terminals to the negative drive terminal.

2. The apparatus of claim 1, including a control circuit having an input, a first set of control signal outputs, and a second set of control signal outputs, the first set of control signal outputs coupled to the first set of control inputs, the second set of control signal outputs coupled to the second set of control inputs,
wherein the control circuit is configured to, responsive to a signal at the input, provide the first set of control signals to the first set of control inputs and the second set of control signals to the second set of control inputs.

3. The apparatus of claim 2, further including:
an intermediate voltage generation circuit that includes a first capacitor coupled between the power supply terminal and the intermediate voltage terminal; and a second capacitor coupled between the intermediate voltage terminal and the reference terminal.

4. The apparatus of claim 3, wherein:
the first set of control signals includes a plurality of cycles;
the second set of control signals includes the plurality of cycles; and
wherein the first and second switch circuits are configured to, responsive to the first and second set of control signals, set the intermediate voltage terminal at an intermediate voltage level in each cycle of the plurality of cycles.

5. The apparatus of claim 4, wherein the control circuit includes a pulse width modulator (PWM) circuit or a pulse density modulator (PDM) circuit, and is configured to, responsive to the signal at the input, adjust at least one of a duty cycle or a cycle period of at least one control signal of the first set of control signals and the second set of control signals.

6. The apparatus of claim 5, wherein the control circuit includes a feedback input coupled to the intermediate voltage terminal, and the control circuit is further configured to, responsive to a voltage level at the feedback input, adjust at least one of the duty cycle or the cycle period of at least one control signal of the first set of control signals and the second set of control signals to maintain the intermediate voltage level at the intermediate voltage terminal.

7. The apparatus of claim 1, further including:
a first filter having a first terminal coupled to the positive drive terminal;
a second filter having a first terminal coupled to the negative drive terminal; and
a speaker coupled to a second terminal of the first filter and a second terminal of the second filter.

8. The apparatus of claim 1, wherein:
the first switch circuit includes a first set of transistors configured to produce a first multi-level output signal at the positive drive terminal in response to the first set of control signals;
the second switch circuit includes a second set of transistors configured to produce a second multi-level output signal at the negative drive terminal in response to the second set of control signals; and
the first multi-level output signal and the second multi-level output signal have opposing polarities.

9. The apparatus of claim 1, wherein the first switch circuit includes:
a first switch coupled between the power supply terminal and the positive drive terminal;
a second switch coupled between the reference terminal and the positive drive terminal; and
a third switch coupled between the intermediate voltage terminal and the positive drive terminal, wherein the third switch includes a first bidirectional switch; and
wherein the second switch circuit includes:
a fourth switch coupled between the power supply terminal and the negative drive terminal;
a fifth switch coupled between the reference terminal and the negative drive terminal; and
a sixth switch coupled between the intermediate voltage terminal and the negative drive terminal, wherein the sixth switch includes a second bidirectional switch.

10. The apparatus of claim 1, wherein the first switch circuit includes:
a first switch and a second switch coupled serially between the power supply terminal and the positive drive terminal;
a third switch and a fourth switch coupled serially between the positive drive terminal and the reference terminal;
a fifth switch coupled between a current terminal of the first switch and the intermediate voltage terminal; and
wherein the second switch circuit includes:
a sixth switch and a seventh switch coupled serially between the power supply terminal and the negative drive terminal;
an eighth switch and a ninth switch coupled serially between the negative drive terminal and the reference terminal; and
a tenth switch coupled between a current terminal of the sixth switch and the intermediate voltage terminal.

11. The apparatus of claim 1, wherein the first switch circuit includes:
a first switch coupled between the power supply terminal and the positive drive terminal;
a second switch coupled between the reference terminal and the positive drive terminal; and
a third switch coupled between the intermediate voltage terminal and the positive drive terminal, wherein the third switch includes a first bidirectional switch, and
wherein the second switch circuit includes:
a fourth switch coupled between the power supply terminal and the negative drive terminal;
a fifth switch coupled between the reference terminal and the negative drive terminal; and
a sixth switch coupled between the intermediate voltage terminal and the negative drive terminal, wherein the sixth switch includes a second bidirectional switch.

12. An apparatus comprising:
a first switch circuit including:
a first switch coupled between a power supply terminal and a positive drive terminal;
a second switch coupled between a reference terminal and the positive drive terminal; and
a third switch coupled between an intermediate voltage terminal and the positive drive terminal, wherein the third switch includes a bidirectional switch; and
a second switch circuit including:
a fourth switch coupled between the power supply terminal and a negative drive terminal;
a fifth switch coupled between the reference terminal and the negative drive terminal; and
a sixth switch coupled between the intermediate voltage terminal and the negative drive terminal.

13. The apparatus of claim 12, wherein:
the first switch circuit further includes a first set of control inputs;
the second switch circuit further includes a second set of control inputs; and
the apparatus further includes a control circuit having an input, a first set of control signal outputs, and a second set of control signal outputs, the first set of control signal outputs coupled to the first set of control inputs, the second set of control signal outputs coupled to the second set of control inputs,
wherein the control circuit is configured to, responsive to a signal at the input, provide a first set of control signals to the first set of control inputs and a second set of control signals to the second set of control inputs.

14. The apparatus of claim 13, further including an intermediate voltage generation circuit including a plurality of output terminals coupled to the power supply terminal, the reference terminal, and the intermediate voltage terminal.

15. The apparatus of claim 13, wherein:
the first set of control signals includes a plurality of cycles;
the second set of control signals includes the plurality of cycles; and
the first set of control signals and the second set of control signals are configured to maintain a stable intermediate voltage level at the intermediate voltage terminal in each cycle of the plurality of cycles.

16. A method comprising:
in a first interval:
connecting a first speaker terminal to a power supply terminal;
connecting a second speaker terminal to an intermediate voltage terminal; and
disconnecting the second speaker terminal from a reference terminal; and
in a second interval:
connecting the first speaker terminal to the intermediate voltage terminal; and
connecting the second speaker terminal to the reference terminal.

17. The method of claim 16, further including:
in a third interval:
connecting the first speaker terminal to the intermediate voltage terminal; and
connecting the second speaker terminal to the intermediate voltage terminal; and
in a fourth interval:
connecting the first speaker terminal to the intermediate voltage terminal;
connecting the second speaker terminal to the intermediate voltage terminal; and
disconnecting the second speaker terminal from the reference terminal.

18. The method of claim 17, wherein:
the first speaker terminal is a positive speaker terminal, and the second speaker terminal is a negative speaker terminal; or
the first speaker terminal is the negative speaker terminal and the second speaker terminal is the positive speaker terminal.

19. The method of claim 16, wherein:
in the first interval, charges are transferred from a first capacitor to a second capacitor via the first speaker terminal, a speaker, the second speaker terminal, and the intermediate voltage terminal, wherein the first capacitor is coupled between the power supply terminal and the intermediate voltage terminal, and the second capacitor is coupled between the intermediate voltage terminal and the reference terminal; and
in the second interval, charges are transferred from the second capacitor to the reference terminal via the intermediate voltage terminal, the first speaker terminal, the speaker, and the second speaker terminal.

20. The method of claim 16, wherein the first interval and the second interval occur within a switching cycle.
